(19) United States
(12) Patent Application Publication
(10) Pub. No.: US 2024/0136489 A1
(43) Pub. Date: Apr. 25, 2024

(54) DISPLAY DEVICE AND MANUFACTURING METHOD THEREOF

(71) Applicant: Samsung Display Co., LTD., Yongin-si (KR)

(72) Inventor: Bo Geon JEON, Yongin-si (KR)

(21) Appl. No.: 18/488,910

(22) Filed: Oct. 16, 2023

(30) Foreign Application Priority Data
Oct. 24, 2022 (KR) 10-2022-0138608

(51) Int. Cl. H01L 33/62; H01L 25/075; H01L 33/38; H01L 33/50

(52) U.S. Cl. CPC H01L 33/62; H01L 25/0753; H01L 33/382; H01L 33/505; H01L 2933/0016; H01L 2933/0066

(57) ABSTRACT

A display device may include a first electrode above a surface of a substrate, light-emitting elements including a first end portion above, contacting, and electrically connected to, the first electrode, a second end portion opposite to the first end portion with respect to a direction that is perpendicular to the surface of the substrate, a bonding electrode, a second layer, an active layer, a first layer, and a third layer having conductivity by doping an impurity into an intrinsic semiconductor layer, an intermediate layer over the light-emitting elements, and exposing the second end portion, and a second electrode above the intermediate layer, and contacting and electrically connected to the second end portion.

### CROSS-REFERENCE TO RELATED APPLICATION

This application claims priority to, and the benefit of, Korean patent application No. 10-2022-0138608 filed on Oct. 25, 2022, in the Korean Intellectual Property Office, the entire disclosure of which is incorporated herein by reference.

### BACKGROUND

### 1. Field

The present disclosure generally relates to a display device, and to a manufacturing method thereof.

### 2. Related Art

Recently, as interest in information displays is increased, research and development of display devices have been continuously conducted.

### SUMMARY

Embodiments provide a display device having improved reliability.

Embodiments also provide a manufacturing method of the above-described display device.

In accordance with an aspect of the present disclosure, there is provided a display device including a first electrode above a surface of a substrate, light-emitting elements including a first end portion above, contacting, and electrically connected to, the first electrode, a second end portion opposite to the first end portion with respect to a direction that is perpendicular to the surface of the substrate, a bonding electrode, a second layer, an active layer, a first layer, and a third layer having conductivity by doping an impurity into an intrinsic semiconductor layer, an intermediate layer over the light-emitting elements, and exposing the second end portion, and a second electrode above the intermediate layer, and contacting and electrically connected to the second end portion.

The bonding electrode may be at the first end portion, and electrically connected to the first electrode, wherein the third layer is at the second end portion, and electrically connected to the second electrode.

The first layer may include an n-type semiconductor layer, and the second layer may include a p-type semiconductor layer.

The intermediate layer may include an organic layer.

The display device may further include a first bank defining an opening above the first electrode to expose an area of the first electrode, and a cover layer above the second electrode.

The intermediate layer may be between the first bank and the light-emitting elements in the opening of the first bank in plan view, thereby fixing the light-emitting elements, and has a flat surface.

The display device may further include a color conversion layer including a color conversion pattern above the cover layer and corresponding to the light-emitting elements, and a second bank adjacent to the color conversion pattern, above the cover layer, and corresponding to the first bank, and a color filter layer above the color conversion layer, and configured to selectively transmit light emitted from the color conversion layer.

The display device may further include a conductive pattern between the first electrode and the first end portion of the light-emitting elements.

In accordance with another aspect of the present disclosure, there is provided a display device including a substrate including an emission area and a non-emission area, a passivation layer above a surface of the substrate, a (1-1)th electrode, a (1-2)th electrode, and a (1-3)th electrode above the passivation layer, and spaced apart, a first bank above the (1-1)th electrode, the (1-2)th electrode, the (1-3)th electrode, and the passivation layer, and defining an opening exposing respective areas of the (1-1)th electrode, the (1-2)th electrode, and the (1-3)th electrode, first light-emitting elements including a first end portion above, contacting, and electrically connected to the (1-1)th electrode, and a second end portion opposite to the first end portion in a direction perpendicular to the surface of the substrate, second light-emitting elements including a first end portion above, contacting, and electrically connected to the (1-2)th electrode, and a second end portion opposite to the first end portion in the direction perpendicular to the surface of the substrate, third light-emitting elements each including a first end portion above, contacting, and electrically connected to the (1-3)th electrode, and a second end portion opposite to the first end portion in the direction perpendicular to the surface of the substrate, an intermediate layer over the first light-emitting elements, the second light-emitting elements, the third light-emitting elements, and the first bank, and exposing the second end portions of the first light-emitting elements, the second light-emitting elements, and the third light-emitting elements, and a second electrode above the intermediate layer, contacting the second end portions of the first light-emitting elements, the second light-emitting elements, and the third light-emitting elements, and electrically connected to the first light-emitting elements, the second light-emitting elements, and the third light-emitting elements, wherein the first light-emitting elements, the second light-emitting elements, and the third light-emitting elements include a bonding electrode, a second layer, an active layer, a first layer, and a third layer, which has conductivity by doping an impurity into an intrinsic semiconductor layer, that are sequentially arranged toward the second electrode.

The bonding electrode may be at the first end portion, and may be electrically connected to a respective one of the (1-1)th electrode, the (1-2)th electrode, and the (1-3)th electrode, wherein the third layer is at the second end portion, and is electrically connected to the second electrode.

The first layer may include an n-type semiconductor layer, and the second layer may include a p-type semiconductor layer.

In accordance with still another aspect of the present disclosure, there is provided a method of manufacturing a display device, the method including forming a first electrode above a surface of a substrate, forming, above the first electrode, a first bank defining an opening exposing an area of the first electrode, preparing light-emitting elements including a first end portion, and a second end portion that is opposite to the first end portion, transferring the light-emitting elements such that the first end portion contacts the first electrode, forming a metal layer over the light-emitting elements, forming, above the metal layer, a photosensitive pattern exposing an area of the metal layer corresponding to the second end portion, forming a metal pattern exposing the second end portion by removing the area of the metal layer through an etching process using the photosensitive pattern as an etching mask, exposing the metal pattern by removing the photosensitive pattern, doping the metal pattern and the second end portion with an impurity, exposing the light-emitting elements and the first bank by removing the metal pattern, and forming an intermediate layer over the light-emitting elements and the first bank.

The forming of the intermediate layer may include coating an intermediate base layer over the light-emitting elements and the first bank, curing the intermediate base layer, and exposing the second end portion by removing a portion of the intermediate base layer through an ashing process.

The intermediate layer may include an organic layer.

The method may further include forming, above the intermediate layer, a second electrode contacting the second end portion to be electrically connected to the light-emitting elements.

The light-emitting elements may include a bonding electrode at the first end portion and contacting the first electrode, a second layer above the bonding electrode, an active layer above the second layer, a first layer above the active layer, and a third layer above the first layer, at the second end portion, and contacting the second electrode.

In the transferring of the light-emitting elements, the first layer may include an n-type semiconductor layer, the second layer includes a p-type semiconductor layer, and the third layer includes an intrinsic semiconductor layer.

In the doping the metal pattern and the second end portion, the third layer may have conductivity by doping the impurity into the intrinsic semiconductor layer.

In the doping the metal pattern and the second end portion, the metal pattern may include a barrier layer covering the first bank, the first electrode, and a side of the light-emitting elements.

The metal layer may include at least one of indium zinc oxide, aluminum, and/or indium gallium zinc oxide.

### BRIEF DESCRIPTION OF THE DRAWINGS

Embodiments will now be described more fully hereinafter with reference to the accompanying drawings, which may be embodied in different forms and should not be construed as limited to the embodiments set forth herein. These embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a schematic plan view illustrating a display device in accordance with one or more embodiments of the present disclosure.

FIGS. 2 and 3 are schematic cross-sectional views illustrating a display panel shown in FIG. 1.

FIG. 4 is a schematic circuit diagram illustrating an electrical connection relationship of components included in each pixel shown in FIG. 1 in accordance with one or more embodiments of the present disclosure.

FIG. 5 is a schematic view illustrating light-emitting elements grown on a growth substrate.

FIG. 6 is a schematic cross-sectional view illustrating a pixel in accordance with one or more embodiments of the present disclosure.

FIGS. 7 and 8 are schematic views illustrating a light-emitting element shown in FIG. 6.

FIGS. 9 and 10 are schematic cross-sectional views illustrating a pixel including the light-emitting element shown in FIG. 7.

FIGS. 11 to 13 are schematic cross-sectional views illustrating a pixel in accordance with one or more embodiments of the present disclosure.

FIGS. 14 to 23 are schematic cross-sectional views sequentially illustrating a manufacturing method of a pixel in accordance with one or more embodiments of the present disclosure.

FIG. 24 is a schematic cross-sectional view taken along line I-I′ shown in FIG. 1.

FIGS. 25 to 28 are schematic views illustrating application examples of the display device in accordance with one or more embodiments of the present disclosure.

### DETAILED DESCRIPTION

Aspects of some embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may have various modifications and may be embodied in different forms, and should not be construed as being limited to only the illustrated embodiments herein. Further, each of the features of the various embodiments of the present disclosure may be combined or combined with each other, in part or in whole, and technically various interlocking and driving are possible. Each embodiment may be implemented independently of each other or may be implemented together in an association. The described embodiments are provided as examples so that this disclosure will be thorough and complete, and will fully convey the aspects of the present disclosure to those skilled in the art, and it should be understood that the present disclosure covers all the modifications, equivalents, and replacements within the idea and technical scope of the present disclosure. Accordingly, processes, elements, and techniques that are not necessary to those having ordinary skill in the art for a complete understanding of the aspects of the present disclosure may not be described.

Unless otherwise noted, like reference numerals, characters, or combinations thereof denote like elements throughout the attached drawings and the written description, and thus, descriptions thereof will not be repeated. Further, parts that are not related to, or that are irrelevant to, the description of the embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Thus, the regions illustrated in the drawings are schematic in nature and their shapes are not intended to illustrate the actual shape of a region of a device and are not intended to be limiting. Additionally, as those skilled in the art would realize, the described embodiments may be modified in various ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. Also, in this specification, the term “connection” or “coupling” may inclusively mean connection or physical and/or electrical coupling. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled,” or “directly on,” refers to one component directly connecting or coupling another component, or being on another component, without an intermediate component. In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of this disclosure, expressions, such as “at least one of,” or “any one of,” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expression, such as “at least one of A and B” and “at least one of A or B” may include A, B, or A and B. As used herein, “or” generally means “and/or,” and the term “and/or” includes any and all combinations of one or more of the associated listed items. For example, the expression, such as “A and/or B” may include A, B, or A and B. Similarly, expressions, such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

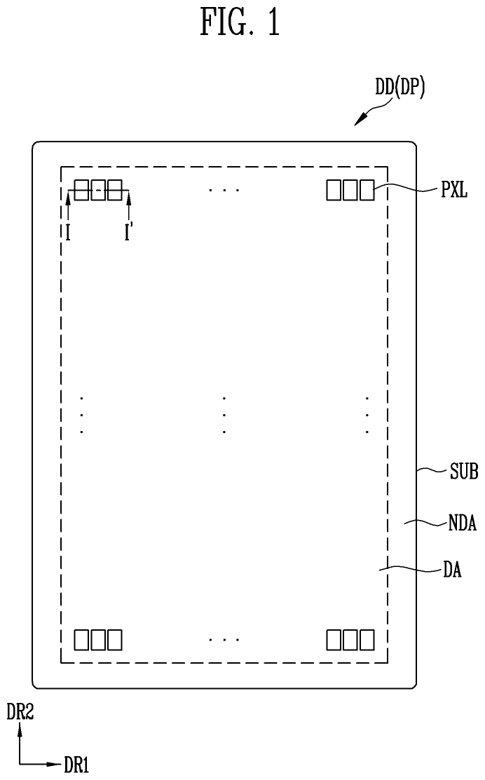

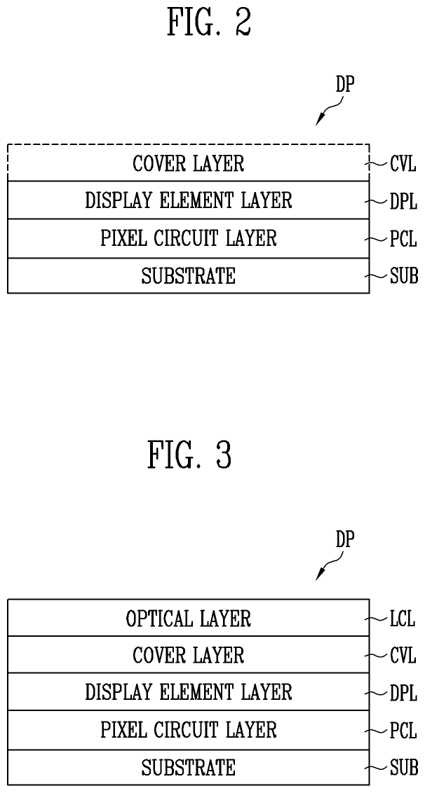

FIG. 1 is a schematic plan view illustrating a display device DD in accordance with one or more embodiments of the present disclosure. FIGS. 2 and 3 are schematic cross-sectional views illustrating a display panel DP shown in FIG. 1.

In FIG. 1, for convenience of description, a structure of the display device DD, for example, the display panel DP provided in the display device DD, is briefly illustrated based on a display area DA in which an image is displayed.

Referring to FIGS. 1 to 3, the display device DD may be provided in various shapes. For example, the display device DD may be provided in a rectangular plate shape having two pairs of sides parallel to each other, but the present disclosure is not limited thereto. In case that the display device DD is provided in the rectangular plate shape, any one pair of sides among the two pairs of sides may be provided longer than the other pair of sides.

The display panel DP (or the display device DD) may include a substrate SUB and pixels PXL.

The substrate SUB may include a transparent insulating material to enable light to be transmitted therethrough. The substrate SUB may be a rigid substrate or a flexible substrate.

The rigid substrate may be, for example, one of a glass substrate, a quartz substrate, a glass ceramic substrate, and a crystalline glass substrate.

The flexible substrate may be one of a film substrate and a plastic substrate, which include a polymer organic material. For example, the flexible substrate may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and/or cellulose acetate propionate.

One area on the substrate SUB may be provided as the display area DA such that the pixels PXL are located therein, and the other area on the substrate SUB may be provided as a non-display area NDA. For example, the substrate SUB may include the display area DA including pixel areas in which the respective pixels PXL are located, and the non-display area NDA located at the periphery of the display area DA (or adjacent to the display area DA). The display area DA may be an area in which the pixels PXL are provided to display an image. The non-display area NDA is an area in which the pixels PXL are not provided, and may be an area in which the image is not displayed.

The non-display area NDA may be located adjacent to the display area DA. The non-display area NDA may be located at at least one side of the display area DA. For example, the non-display area NDA may surround a circumference (or edge) of the display area DA. A line part electrically connected to each pixel PXL and a driver that is electrically connected to the line part and drives the pixel PXL may be located in the non-display area NDA.

Each of the pixels PXL may be provided in the display area DA of the substrate SUB. In one or more embodiments, the pixels PXL may be arranged in a stripe arrangement structure or the like in the display area DA, but the present disclosure is not limited thereto.

The display panel DP may include a pixel circuit layer PCL and a display element layer DPL, which are sequentially located on the substrate SUB.

The pixel circuit layer PCL may be located on the substrate SUB, and may include a plurality of transistors and signal lines electrically connected to the transistors. For example, each transistor may have a form in which a semiconductor layer, a gate electrode, a first terminal, and a second terminal are sequentially stacked with an insulating layer interposed therebetween. The semiconductor layer may include amorphous silicon, polysilicon, low temperature polysilicon, and an organic semiconductor. The gate electrode, the first terminal, and the second terminal may include one of aluminum (Al), copper (Cu), titanium (Ti), and molybdenum (Mo), but the present disclosure is not limited thereto. Also, the pixel circuit layer PCL may include at least one insulating layer.

The display element layer DPL may be located on the pixel circuit layer PCL. The display element layer DPL may include a light-emitting element emitting light. The light-emitting element may be, for example, an organic light-emitting diode, an inorganic light-emitting element including an inorganic light-emitting material, or a light-emitting element emitting light by changing a wavelength of light emitted, using a quantum dot.

A cover layer CVL may be selectively located on the display element layer DPL. The cover layer CVL may be an encapsulation substrate or have the form of an encapsulation layer provided as a multi-layer. When the cover layer CVL has the form of the encapsulation layer, the cover layer CVL may include an inorganic layer and/or an organic layer. For example, the cover layer CVL may have a form in which an inorganic layer, an organic layer, and an inorganic layer are sequentially stacked. The cover layer CVL may reduce or prevent external air and moisture from infiltrating into the display element layer DPL and the pixel circuit layer PCL.

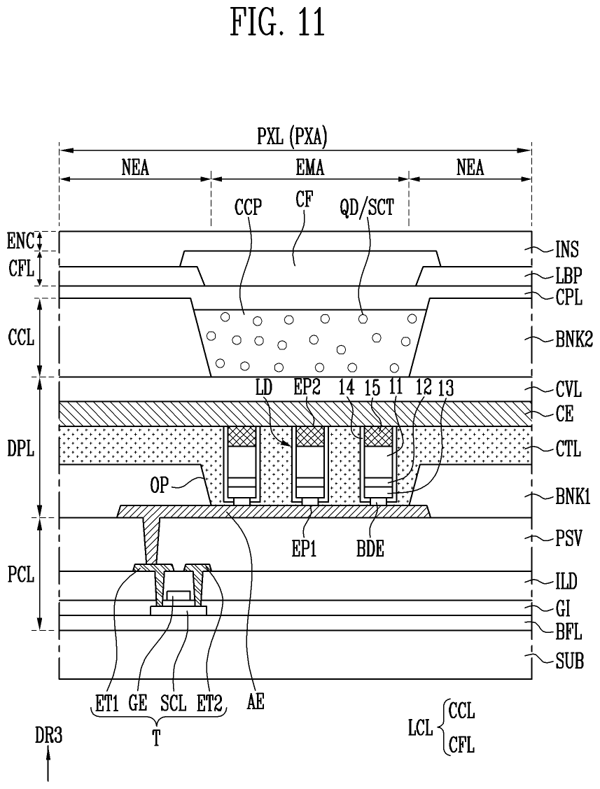

In some embodiments, as shown in FIG. 3, an optical layer LCL may be located on the cover layer CVL. The optical layer LCL may change a wavelength (or color) of light emitted from the display element layer DPL by using a quantum dot, and may allow light having a corresponding wavelength (or corresponding color) to be selectively transmitted therethrough in an image display direction of the display device DD by using a color filter. The optical layer LCL may be formed on the display element layer DPL through a continuous process or may be formed through an adhesion process using an adhesive layer. The optical layer LCL will be described later with reference to FIGS. 11 to 13.

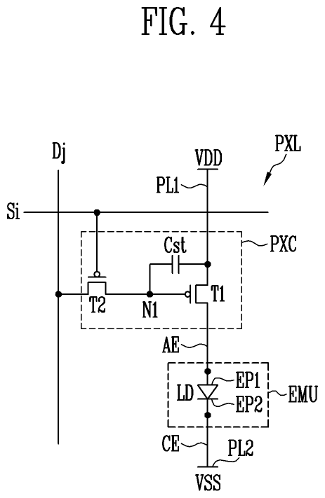

FIG. 4 is a schematic circuit diagram illustrating an electrical connection relationship of components included in each pixel PXL shown in FIG. 1 in accordance with one or more embodiments of the present disclosure.

For example, FIG. 4 illustrates an electrical connection relationship of components included in a pixel PXL applicable to an active matrix type display device in accordance with one or more embodiments of the present disclosure. However, the kinds of the components included in the pixel PXL applicable to the embodiments of the present disclosure are not limited thereto.

Referring to FIGS. 1 to 4, the pixel PXL may include an emission component EMU that generates light with a luminance corresponding to a data signal. Also, the pixel PXL may selectively further include a pixel circuit PXC for driving the emission component EMU.

The emission component EMU may include a light-emitting element LD electrically connected between a first power line PL1 to which a voltage of a first driving power source VDD, and a second power line PL2 to which a voltage of a second power source VSS is applied. For example, the emission component EMU may include at least one light-emitting element LD connected between a first electrode AE (or pixel electrode) and a second electrode CE (or common electrode). In one or more embodiments, the first electrode AE is an anode, and the second electrode CE may be a cathode.

The light-emitting element LD included in the emission component EMU may include a first end portion EP1 electrically connected to the first driving power source VDD through the first electrode AE, and a second end portion electrically connected to the second driving power source VSS through the second electrode CE. The first driving power source VDD and the second driving power source VSS may have different potentials. For example, the first driving power source VDD may be set as a high-potential power source, and the second driving power source VSS may be set as a low-potential power source. A potential difference between the first and second driving power sources VDD and VSS may be set equal to or higher than a threshold voltage of the light-emitting element LD during an emission period of the pixel PXL.

As described above, the light-emitting element LD electrically connected between the first electrode AE and the second electrode CE, to which voltages having different potentials are respectively supplied, may form an effective light source, and may implement an emission component EMU of each pixel PXL.

The light-emitting element LD may emit light with a luminance corresponding to a driving current supplied through the pixel circuit PXC. For example, the pixel circuit PXC may supply, to the emission component EMU, a driving current corresponding to a grayscale value of corresponding frame data during each frame period. The driving current supplied to the emission component EMU may flow through the light-emitting element LD. Accordingly, the emission component EMU may emit light while the light-emitting element LD emits light with a luminance corresponding to the driving current.

The pixel circuit PXC may be electrically connected to a scan line Si and a data line Dj of the pixel PXL. For example, in case that a pixel PXL is located on an ith (i is a natural number) row and a jth (j is a natural number) column of the display area DA of the display panel DP (or the substrate SUB), a pixel circuit PXC of the pixel PXL may be electrically connected to an ith scan line Si and a jth data line Dj of the display area DA. The pixel circuit PXC may include first and second transistors T1 and T2 and a storage capacitor Cst. However, the structure of the pixel circuit PXC is not limited to the one or more embodiments corresponding to FIG. 4.

The first transistor T1 is a driving transistor for controlling the driving current applied to the emission component EMU, and may be electrically connected between the emission component EMU and the first driving power source VDD. For example, a first terminal of the first transistor T1 may be electrically connected to the emission component EMU, a second terminal of the first transistor T1 may be electrically connected to the first driving power source VDD through the first power line PL1, and a gate electrode of the first transistor T1 may be electrically connected to a first node N1. The first transistor T1 may control an amount of driving current flowing from the first driving power source VDD to the emission component EMU according to a voltage applied to the first node N1.

The second transistor T2 is a switching transistor that selects a pixel PXL in response to a scan signal applied to the scan line Si, and that activates the pixel PXL, and may be electrically connected between the data line Dj and the first node N1. A first terminal of the second transistor T2 may be electrically connected to the data line Dj, a second terminal of the second transistor T2 may be electrically connected to the first node N1, and a gate electrode of the second transistor T2 may be electrically connected to the scan line Si. The first terminal and the second terminal of the second transistor T2 are different terminals. For example, when the first terminal is a source electrode, and the second terminal may be a drain electrode.

The second transistor T2 is turned on when the scan signal having a voltage (e.g., a low voltage) at which the second transistor T2 can be turned on is supplied from the scan line Si, to electrically connect the data line Dj and the first node N1 to each other. A data signal of a corresponding frame is supplied to the data line Dj. Accordingly, the data signal is transferred to the first node N1. The data signal transferred to the first node N1 is charged in the storage capacitor Cst.

One electrode of the storage capacitor Cst may be electrically connected to the second terminal of the first transistor T1 (or the first driving power source VDD), and the other electrode of the storage capacitor Cst may be electrically connected to the first node N1. The storage capacitor Cst may store a data voltage corresponding to the data signal supplied to the first node N1, and may maintain the charged voltage until a data signal of a next frame is supplied.

Although the pixel circuit PXC including the second transistor T2 for transferring a data signal to the inside of the pixel PXL, the storage capacitor Cst for storing the data signal, and the first transistor T1 for supplying a driving current corresponding to the data signal to the light-emitting element LD is illustrated in FIG. 4, the present disclosure is not limited thereto, and the structure of the pixel circuit PXC may be variously modified.

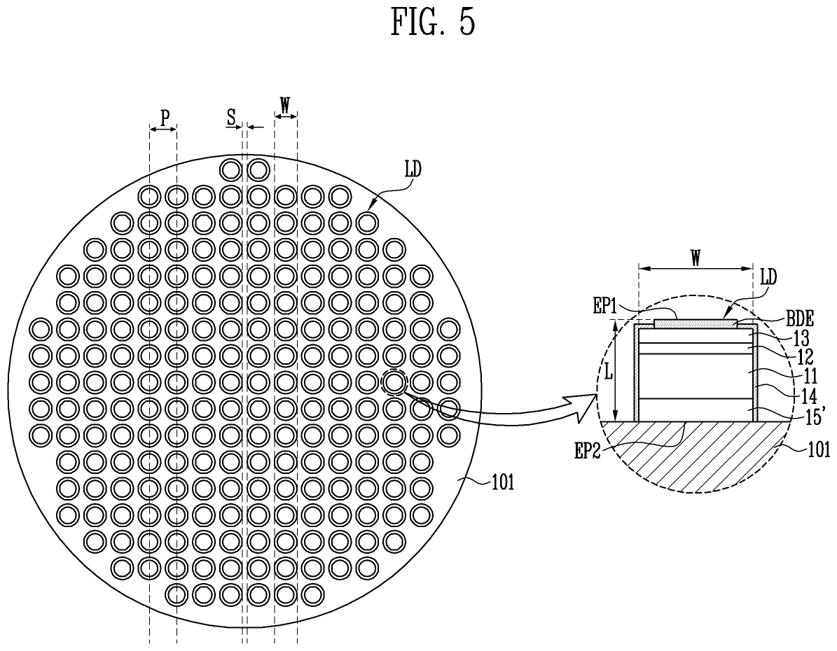

FIG. 5 is a schematic view illustrating light-emitting elements LD grown on a growth substrate 101.

Referring to FIGS. 1 to 5, each light-emitting element LD may be manufactured and located on the growth substrate 101.

The growth substrate 101 may be configured as a conductive substrate or an insulative substrate. For example, the growth substrate 101 may be formed of at least one of SiC, Si, GaAs, GaN, ZnO, GaP, InP, Ge, and/or Ga₂O₃.

Each light-emitting element LD may emit light as electrons and holes are recombined according to a current flowing between a first end portion EP1 and a second end portion EP2. By using such a principle, each light-emitting element LD may be used as a light source (or light-emitting source) for various light-emitting devices, including a pixel PXL.

Each light-emitting element LD may include a first layer 11, a second layer 13, and an active layer 12 interposed between the first layer 11 and the second layer 13. The light-emitting element LD may further include a bonding electrode BDE and a buffer semiconductor layer 15′. Each light-emitting element LD may be implemented as a vertical light-emitting stack structure (or vertical light-emitting stack pattern) in which the buffer semiconductor layer 15′, the first layer 11, the active layer 12, the second layer 13, and the bonding electrode BDE are sequentially stacked on the growth substrate 101.

The light-emitting element LD may be provided in a shape extending in one direction (or a thickness direction of the growth substrate 101). When assuming that an extending direction of the light-emitting element LD is a length direction, the light-emitting element LD may include the first end portion EP1 and the second end portion EP2, which are opposite to each other along the length direction. In one or more embodiments, the length direction may be parallel to the thickness direction of the growth substrate 101. The bonding electrode BDE may be located at the first end portion EP1 of each light-emitting element LD, and the buffer semiconductor layer 15′ may be located at the second end portion EP2 of the corresponding light-emitting element LD.

The above-described light-emitting element LD may include a light-emitting diode (LED) manufactured to have a diameter and/or a length L to a degree of nano scale to micro scale. In one or more embodiments, the light-emitting element LD may have a width W of about 5 μm or so and a length L of about 5.5 μm or so, but the present disclosure is not limited thereto. The size of the light-emitting element LD may be variously changed to accord with requirement conditions (or design conditions) of a lighting device or a self-luminous display device, to which each light-emitting element LD is applied.

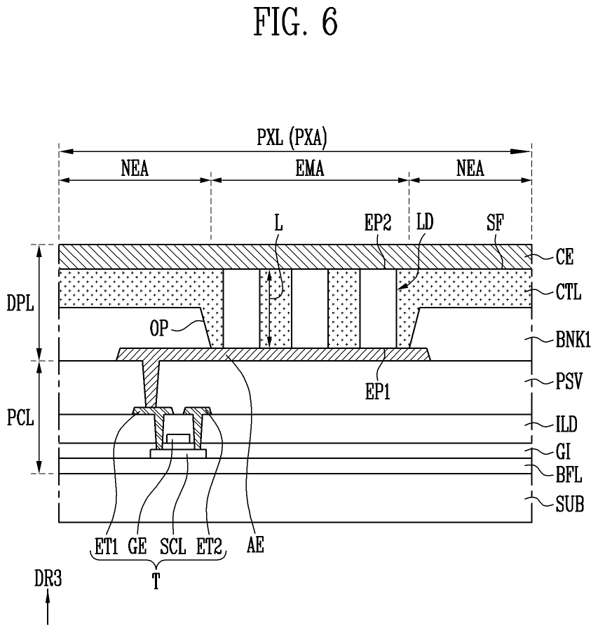

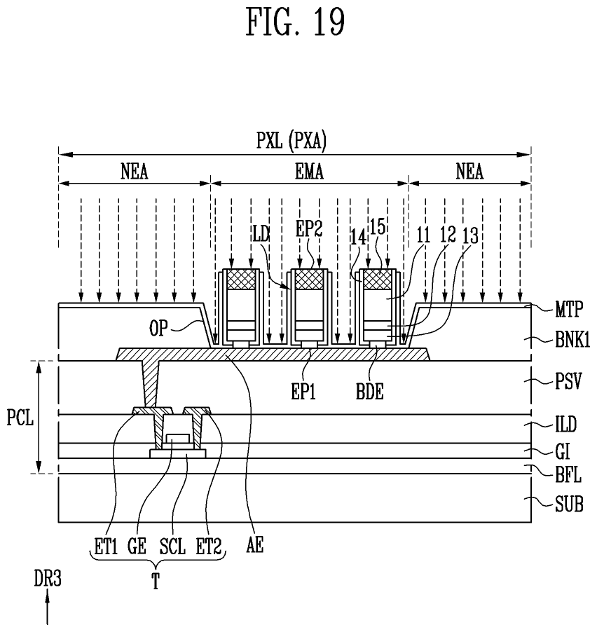

The buffer semiconductor layer 15′ is a layer stacked on the top of the growth substrate 101, and may be formed of GaN undoped with an impurity. For example, the buffer semiconductor layer 15′ may be an intrinsic semiconductor layer. The buffer semiconductor layer 15′ may be provided to protect the active layer 12 from laser caused by laser lift-off or the like in a process of manufacturing the light-emitting element LD, but the present disclosure is not limited thereto. The buffer semiconductor layer 15′ may have a band gap energy that is less than a band gap energy that the active layer 12 has, but the present disclosure is not limited thereto. The buffer semiconductor layer 15′ may have conductivity as the impurity is doped after the buffer semiconductor layer 15′ is transferred to a first electrode (see “AE” shown in FIG. 6) located in a display element layer (see “DPL” shown in FIG. 6). This will be described in detail later with reference to FIG. 19.

The first layer 11 (or a first semiconductor layer) may be formed on the buffer semiconductor layer 15′, and may include, for example, at least one n-type semiconductor layer. For example, the first layer 11 may include any one semiconductor material among InAlGaN, GaN, AlGaN, InGaN, AlN, and InN, and may be an n-type semiconductor layer doped with a first conductive dopant (or n-type dopant), such as Si, Ge or Sn. However, the material constituting the first layer 11 is not limited thereto. In addition, the first layer 11 may be configured with various materials. In one or more embodiments, the first layer 11 may include a gallium nitride (GaN) semiconductor material doped with the first conductive dopant (or n-type dopant).

The active layer 12 may be formed on the first layer 11 along the thickness direction of the growth substrate 101, and may be a region in which electrons and holes are recombined. As the electrons and the holes are recombined in the active layer 12, light (or beam) may be generated, which has a level changed to a low energy level and has a wavelength corresponding to the low energy level. The active layer 12 may be formed, including a semiconductor material having, for example, a composition formula of InₓAl_{y}Ga_{1-x-y}N (0≤x≤1, 0≤y≤1, 0≤x+y≤1), and may be formed in a single- or multi-quantum well structure. For example, when the active layer 12 is formed in the multi-quantum well structure, a barrier layer, a strain reinforcing layer, and a well layer may be periodically and repeatedly stacked as one unit. However, the structure of the active layer 12 is not limited to the above-described embodiments. The active layer 12 may include a first surface in contact with the first layer 11 and a second surface in contact with the second layer 13.

The second layer 13 (or a second semiconductor layer) may be form on the second surface of the active layer 12, and may provide holes to the active layer 12. The second layer 13 may include a semiconductor layer having a type different from the type of the first layer 11. For example, the second layer 13 may include at least one p-type semiconductor layer. For example, the second layer 13 may include at least one semiconductor material among InAlGaN, GaN, AlGaN, InGaN, AlN, and/or InN, and may include a p-type semiconductor layer doped with a second conductive dopant (or p-type dopant), such as Mg, Zn, Ca, Sr or Ba. However, the material constituting the second layer 13 is not limited thereto. In addition, the second layer 13 may be configured with various materials. In one or more embodiments, the second layer 13 may include a gallium nitride (GaN) semiconductor material doped with the second conductive dopant (or p-type dopant).

The bonding electrode BDE may be formed on the second layer 13, and may be bonded to the first electrode AE of the display element layer DPL. In some embodiments, each light-emitting element LD may selectively have a separate contact electrode in ohmic contact with the second layer 13 between the second layer 13 and the bonding electrode BDE.

Each light-emitting element LD may further include an insulating film 14. The insulating film 14 may cover an outer circumferential surface (or surface) of the vertical light-emitting stack structure. The insulating film 14 may include a transparent insulating material. Various materials having an insulating property may be used as the material of the insulating film 14. In some embodiments, the insulating film 14 may be omitted, and may be provided to only a portion of the vertical light-emitting stack structure.

The insulating film 14 may be provided in the form of a single layer, or may be provided in the form of a multi-layer including two layers. For example, when the insulating film 14 may be configured as a double layer including a first insulating layer and a second insulating layer, which are sequentially stacked, the first insulating layer and the second insulating layer may be made of different materials (or substances), and may be formed through different processes. In some embodiments, the first insulating layer and the second insulating layer may be formed of the same material through a continuous process.

A plurality of light-emitting elements LD formed on the growth substrate 10 may be cut along a cutting line by using laser or the like, or may be separated into pieces through an etching process. The plurality of light-emitting elements LD may be in a state in which the plurality of light-emitting elements LD are separable from the growth substrate 101 through a laser lift-off process.

In FIG. 5, the reference character “P” may refer to a pitch distance between the light-emitting elements LD, the reference character “S” may refer to a separation distance between the light-emitting elements LD, and the reference character “W” may refer to the width of the light-emitting elements LD. Although a case where a sectional shape of the light-emitting element LD is a quadrangular shape is disclosed in FIG. 5, the present disclosure is not limited thereto, and the light-emitting element LD may have another sectional shape, such as a circular sectional shape, instead of the quadrangular sectional shape according to a method in which the light-emitting element LD is manufactured on the growth substrate 101.

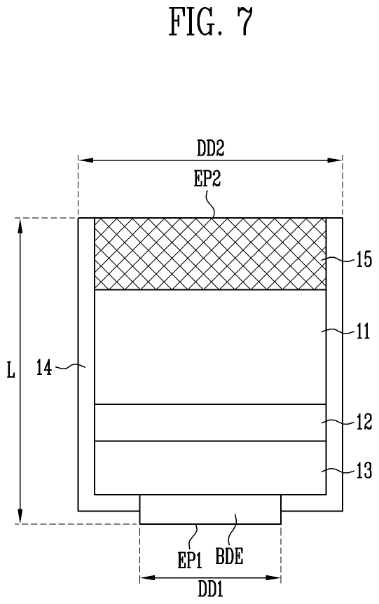

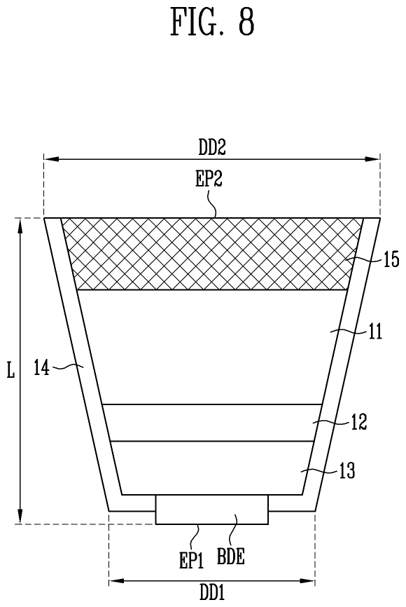

FIG. 6 is a schematic cross-sectional view illustrating a pixel PXL in accordance with one or more embodiments of the present disclosure. FIGS. 7 and 8 are schematic views illustrating each light-emitting element LD shown in FIG. 6.

In FIG. 6, the pixel PXL is simplified and illustrated. However, the present disclosure is not limited thereto. In relation to embodiments shown in FIGS. 6 to 8, portions that are different from those of the above-described embodiments will be mainly described to avoid redundancy.

Referring to FIGS. 1 to 8, the pixel PXL in accordance with the embodiments of the present disclosure may be located in a pixel area PXA provided in a substrate SUB. The pixel area PXA is one area of the display area DA, and may include an emission area EMA and a non-emission area NEA.

The pixel PXL may include the substrate SUB, a pixel circuit layer PCL, and a display element layer DPL.

The substrate SUB may include a transparent insulating material to allow light to be transmitted therethrough. The substrate SUB may be a rigid substrate or a flexible substrate.

Circuit elements (e.g., a transistor T) and signal lines electrically connected to the circuit elements, which constitute a pixel circuit PXC, may be located in the pixel circuit layer PCL. The pixel circuit layer PCL may include at least one insulating layer in addition to the circuit elements and the signal lines. For example, the pixel circuit layer PCL may include a buffer layer BFL, a gate-insulating layer GI, an interlayer insulating layer ILD, and a passivation layer PSV, which are sequentially stacked on the substrate SUB along a third direction DR3 (or a thickness direction of the substrate SUB).

The buffer layer BFL may be entirely located on the substrate SUB. The buffer layer BFL may reduce or prevent the likelihood of an impurity being diffused into transistors T included in the pixel circuit PXC. The buffer layer BFL may be an inorganic insulating layer including an inorganic material. The buffer layer BFL may include at least one of silicon nitride (SiNₓ), silicon oxide (SiOₓ), and/or silicon oxynitride (SiOₓN_{y}), or may include at least one of metal oxides, such as aluminum oxide (AlOₓ). The buffer layer BFL may be provided as a single layer, but also may be provided as a multi-layer including at least two layers. When the buffer layer BFL is provided as the multi-layer, the layers may be formed of the same material or may be formed of different materials. The buffer layer BFL may be omitted according to a material of the substrate SUB, a process condition, and the like.

The gate-insulating layer GI may be entirely located on the buffer layer BFL. The gate-insulating layer GI may include the same material as the above-described buffer layer BFL, or may include a suitable (or selected) material among the materials disclosed as the material constituting the buffer layer BFL. For example, the gate-insulating layer GI may be an inorganic insulting layer including an inorganic material.

The interlayer insulating layer ILD may be entirely provided and/or formed on the gate-insulating layer GI. The interlayer insulating layer ILD may include the same material as the above-described buffer layer BFL, or may include an appropriate (or selected) material among the materials disclosed as the material constituting the buffer layer BFL.

The passivation layer PSV may be entirely provided and/or formed on the interlayer insulating layer ILD. The passivation layer PSV may be an inorganic insulating layer including an inorganic material or an organic insulating layer including an organic material. The inorganic insulating layer may include, for example, at least one of silicon nitride (SiNₓ), silicon oxide (SiOₓ), and/or silicon oxynitride (SiOₓN_{y}), or may include at least one of metal oxides, such as aluminum oxide (AlOₓ). The organic insulating layer may include, for example, at least one of acrylic resin, epoxy resin, phenolic resin, polyamide resin, polyimide resin, unsaturated polyester resin, poly-phenylene ether resin, poly-phenylene sulfide resin, and/or benzocyclobutene resin. In one or more embodiments, the passivation layer PSV may be an organic insulating layer.

The pixel circuit PXC may include at least one transistor T located on the buffer layer BFL. The transistor T is a driving transistor for controlling a driving current of a light-emitting element LD, and may be the same component as the first transistor T1 described with reference to FIG. 4.

The transistor T may include a semiconductor pattern SCL, a gate electrode GE overlapping a portion of the semiconductor pattern SCL, and a first terminal ET1 and a second terminal ET2, which are electrically connected to the semiconductor pattern SCL.

The gate electrode GE may be provided and/or formed on the gate-insulating layer GI. The gate electrode GE may overlap a portion of the semiconductor pattern SCL. For example, the gate electrode GE may overlap an active pattern of the semiconductor pattern. The gate electrode GE may be formed as a single layer including one selected from the group consisting of copper (Cu), molybdenum (Mo), tungsten (W), aluminum neodymium (AINd), titanium (Ti), aluminum (Al), silver (Ag), and/or any alloy thereof or a mixture thereof, or may be formed in a double- or multi-layer structure including molybdenum (Mo), titanium (Ti), copper (Cu), aluminum (Al), and/or silver (Ag), which is a low-resistance material so as to decrease wiring resistance.

The semiconductor pattern SCL may be provided and/or formed on the buffer layer BFL. For example, the semiconductor pattern SCL may be located between the buffer layer BFL and the gate-insulating layer GI. The semiconductor pattern SCL may be formed of polysilicon, amorphous silicon, an oxide semiconductor, or the like. The semiconductor pattern SCL may include the active pattern, a first contact region, and a second contact region. The active pattern, the first contact region, and the second contact region may be formed of a semiconductor layer undoped or doped with an impurity. For example, the first contact region and the second contact region may be formed of a semiconductor layer doped with the impurity, and the active pattern may be formed of a semiconductor layer undoped with the impurity.

The active pattern of the semiconductor pattern SCL is a region overlapping the gate electrode GE of the transistor T, and may be a channel region. The first contact region of the semiconductor pattern SCL may be in contact with one end of the active pattern. Also, the first contact region may be electrically connected to the first terminal ET1. The second contact region of the semiconductor pattern SCL may be in contact with the other end of the active pattern. Also, the second contact region may be electrically connected to the second terminal ET2.

The first terminal ET1 (or source electrode) may be provided and/or formed on the interlayer insulating layer ILD. The first terminal ET1 may be in contact with the first contact region of the semiconductor pattern SCL through a contact hole penetrating the gate-insulating layer GI and the interlayer insulating layer ILD.

The second terminal ET2 (or drain electrode) may be provided and/or formed on the interlayer insulating layer ILD. The second terminal ET2 may be located on the interlayer insulating layer ILD to be spaced from the first terminal ET1. The second terminal ET2 may be in contact with the second contact region of the semiconductor pattern SCL through a contact hole penetrating the gate-insulating layer GI and the interlayer insulating layer ILD.

In the above-described embodiments, a case where the transistor T is a thin film transistor having a top gate structure is described as an example. However, the present disclosure is not limited thereto, and the structure of the transistor T may be variously modified.

The pixel circuit layer PCL may further include signal lines (e.g., including a scan line, a data line, and the like) and power lines (e.g., the first and second power lines PL1 and PL2 described with reference to FIG. 4), which are electrically connected to the transistor T.

The passivation layer PSV may be located over the above-described transistor T. The passivation layer PSV may be partially opened to expose the first terminal ET1 of the transistor T to the outside.

The display element layer DPL may be located on the passivation layer PSV.

A first electrode AE, light-emitting elements LD, and a second electrode CE, which constitute an emission component EMU, may be located in the display element layer DPL.

The first electrode AE (“a pixel electrode” or “an anode”) may be provided and/or formed on the pixel circuit layer PCL. The first electrode AE may be located on the bottom of the light-emitting elements LD, and may be electrically connected to first end portions EP1 of the light-emitting elements LD. The second electrode CE (“a common electrode” or “a cathode”) may be located on the top of the light-emitting elements LD, and may be electrically connected to second end portions EP2 of the light-emitting elements LD. In a sectional view, the first electrode AE and the second electrode CE may face each other with the light-emitting elements LD interposed therebetween in the third direction DR3.

The first electrode AE may be electrically connected to the first terminal ET1 of the transistor T through a contact hole penetrating the passivation layer PSV. In one or more embodiments, the first electrode AE may be an anode.

The first electrode AE may be configured with a conductive material having reflexibility so as to allow light emitted from the light-emitting elements LD to advance in the image display direction (or front direction) of the display device DD. The conductive material may include an opaque metal suitable for reflecting light emitted from the light-emitting element LD in the image display direction (or desired direction) of the display device DD. The opaque metal may include, for example, metals, such as silver (Ag), magnesium (Mg), aluminum (Al), platinum (Pt), palladium (Pd), gold (Au), nickel (Ni), neodymium (Nd), iridium (Ir), chromium (Cr), titanium (Ti), and/or alloys thereof. In some embodiments, the first electrode AE may include a transparent conductive material (or substance). The transparent conductive material (or substance) may include a conductive oxide, such as indium tin oxide (ITO), indium zinc oxide (IZO), zinc oxide (ZnO), indium gallium zinc oxide (IGZO), or indium tin zinc oxide (ITZO), a conductive polymer, such as poly(3,4-ethylenedioxythiophene (PEDOT), and the like. When the first electrode AE includes a transparent conductive material (or substance), a separate conductive layer may be added, which is formed of an opaque metal for reflecting light emitted from each of light-emitting elements LD in the image display direction of the display device DD. However, the material of the first electrode AE is not limited to the above-described materials.

The first electrode AE may be provided and/or formed as a single layer, but the present disclosure is not limited thereto. In some embodiments, the first electrode AE may be provided and/or formed as a multi-layer in which at least two materials among metals, alloys, conductive oxide, and conductive polymers are stacked. The first electrode AE may be formed as a multi-layer including at least two layers so as to reduce or minimize distortion caused by a signal delay when a signal (or voltage) is transferred to the first end portions EP1 of the light-emitting elements LD. For example, the first electrode AE may be formed as a multi-layer in which indium tin oxide (ITO)/silver (Ag)/indium tin oxide (ITO) are sequentially stacked. When the first electrode AE is formed as the multi-layer, a layer located as an uppermost layer among the layers may be used as a bonding metal bonded to the light-emitting elements LD, but the present disclosure is not limited thereto.

A first bank BNK1 may be provided and/or formed on the first electrode AE. The first bank BNK1 may be a pixel-defining layer that is located in the non-emission area NEA and partitions the emission area EMA of the pixel PXL. The first bank BNK1 may include an opening OP exposing a portion of the first electrode AE. For example, the first bank BNK1 may be partially opened to expose one area of the first electrode AE. In one or more embodiments, the emission area EMA of the pixel PXL and the opening OP of the first bank BNK1 may correspond to each other.

The first bank BNK1 may include at least one light-blocking material and/or a reflective material (or light-scattering material), and thereby may reduce or prevent the likelihood of a light leakage defect in which light is leaked between adjacent pixels PXL. In one or more embodiments, the first bank BNK1 may be an organic insulating layer including an organic material. For example, the first bank BNK1 may be formed of an organic insulating layer including acrylic resin, epoxy resin, phenolic resin, polyamide resin, polyimide resin, and the like. Also, in some embodiments, the first bank BNK1 may include a transparent material. The transparent material may include, for example, polyamide-based resin, polyimide-based resin, and the like, but the present disclosure is not limited thereto. In other embodiments, a reflective material layer may be separately provided and/or formed on the bank BNK so as to further improve the efficiency of light emitted from the pixel PXL.

The light-emitting elements LD may be located on the first electrode AE exposed by the opening OP of the first bank BNK1. After the light-emitting elements LD, which are transferred to a transfer base by a transportation device or the like, are moved to the top of the first bank BNK1 to correspond to the opening OP of the first bank BNK1, the light-emitting elements LD may be retransferred into the opening OP. A first end portion EP1 of each of the light-emitting elements LD may be in contact with the first electrode AE.

Each of the light-emitting elements LD may be provided in a shape extending in one direction as shown in FIGS. 7 and 8. When assuming that an extending direction of each of the light-emitting elements LD is a length direction, each light-emitting element LD may include a first end portion EP1 (or a lower end portion) and a second end portion EP2 (or an upper end portion), which are opposite to each other along the length direction. In one or more embodiments, the length direction may be parallel to the third direction DR3, and may be vertical to a main surface of the substrate SUB (or one surface on which the pixel circuit layer PCL is located). For example, the first end portion EP1 and the second end portion EP2 of each light-emitting element LD may face each other in a vertical direction of the one surface (or s main surface) of the substrate SUB.

Each of the light-emitting elements LD may include a vertical light-emitting stack structure in which a bonding electrode BDE, a second layer 13, an active layer 12, a first layer 11, and a third layer 15 are sequentially stacked along a direction (e.g., the third direction DR3) toward the second electrode CE from the first electrode AE, and an insulating film 14 surrounding an outer circumferential surface (or surface) of the vertical light-emitting stack structure. The bonding electrode BDE may be located at the first end portion EP1 of each of the light-emitting elements LD, and the third layer 15 may be located at the second end portion EP2 of the corresponding light-emitting element LD.

Each of the light-emitting elements LD may have various shapes. For example, each of the light-emitting elements LD may have a rod shape, a bar shape, or a pillar shape. In one or more embodiments, each of the light-emitting elements LD may have a pillar shape in which a diameter DD1 of the first end portion EP1 and a diameter DD2 of the second end portion EP2 are different from each other. For example, each of the light-emitting elements LD may have a pillar shape in which the diameter DD1 of the first end portion EP1 is less than the diameter DD2 of the second end portion EP2, but the present disclosure is not limited thereto.

In one or more embodiments shown in FIG. 7, each light-emitting element LD may have a pillar shape in which a third layer 15, a first layer 11, an active layer 12, and a second layer 13 have the same diameter, and a bonding electrode BDE has a diameter that is less than a diameter of the second layer 13.

In one or more embodiments shown in FIG. 8, each light-emitting element LD may have an inverse tapered shape. A diameter of a third layer 15 located at a second end portion of the light-emitting element LD may be greatest, and a diameter of a bonding electrode BDE located at a first end portion EP1 of the light-emitting element LD may be least. A first layer 11 of the light-emitting element LD may have a diameter that is less than the diameter of the third layer 15, and that is greater than the diameter of the bonding electrode BDE. An active layer 12 of the light-emitting element LD may have a diameter that is less than the diameter of the first layer 11, and that is greater than the diameter of the bonding electrode BDE. A second layer 13 of the light-emitting element LD may have a diameter that is less than the diameter of the active layer 12, and that is greater than the diameter of the bonding electrode BDE.

A length L of each light-emitting element LD in the extending direction (or length direction) may be greater than, or less than, the diameter DD1 of the first end portion EP1 (or a width of a first cross-section) or the diameter DD2 of the second end portion EP2 (or a width of a second cross section). However, the present disclosure is not limited thereto. In some embodiments, the length L of each light-emitting element LD may be equal to the diameter DD1 of the first end portion EP1, or may be equal to the diameter DD2 of the second end portion EP2. The above-described light-emitting elements LD may include a light-emitting diode (LED) manufactured to have diameters DD1 and DD2 and/or a length L to a degree of micrometer scale (or micrometer). In one or more embodiments, the light-emitting element LD may include a vertical LED emitting blue-based light, but the present disclosure is not limited thereto.

The bonding electrode BDE may be bonded to the first electrode AE. The bonding electrode BDE may be selected from gold (Au), tin (Sn), and the like, which have a suitable bonding force (or adhesion force) to facilitate generation and growth of an intermetallic compound. However, the present disclosure is not limited thereto.

The second layer 13 may be formed on the bonding electrode BDE, and may include a p-type semiconductor layer. The second layer 13 may include a lower surface in contact with the bonding electrode BDE, and an upper surface that faces the lower surface and is in contact with the active layer 12.

The active layer 12 may be formed on the second layer 13, and may be a region in which electrons and holes are recombined. The active layer 12 may be formed in a single- or multi-quantum well structure. The active layer 12 may include a second surface in contact with the second layer 13, and a first surface in contact with the first layer 11.

The first layer 11 may be formed on the active layer 12, and may include an n-type semiconductor layer. The first layer 11 may include a lower surface in contact with the active layer 12, and an upper surface that faces the lower surface and is in contact with the third layer 15.

The third layer 15 may be formed on the first layer 11, and may be electrically connected to the second electrode CE while being in contact with the second electrode CE. The third layer 15 may be a semiconductor layer undoped with an impurity (e.g., a semiconductor layer having conductivity), which is obtained by doping the impurity into an intrinsic semiconductor layer. The intrinsic semiconductor layer may be the buffer semiconductor layer 15′ described with reference to FIG. 5. In one or more embodiments, after each light-emitting element LD and the first electrode AE are bonded to each other, the buffer semiconductor layer 15′ located at the second end portion EP2 of the corresponding light-emitting element LD is exposed to the outside, and then the impurity is doped into the buffer semiconductor layer 15′. Therefore, the buffer semiconductor layer 15′ may be formed as the third layer 15 having conductivity.

A bonding method may be used to electrically connect the light-emitting elements LD and the first electrode AE to each other. The bonding method may include an anisotropic conductive film (AFC) bonding method, a laser assist bonding (LAB) method using laser, an ultrasonic bonding method, a ball grid array (BGA) method, a thermo compression (TC) bonding method, and the like. The TC bonding method may mean a method in which the light-emitting elements LD and the first electrode AE are electrically and physically connected to each other by heating the bonding electrode BDE, which is located at the first end portion EP1 of each of the light-emitting elements LD, and the first electrode AE at a temperature that is higher than melting points of the bonding electrode BDE and the first electrode AE, and then applying a pressure to the bonding electrode BDE and the first electrode AE.

After the bonding electrode BDE and the first electrode AE are in contact with each other as the light-emitting elements LD are located in the opening OP of the first bank BNK1, the light-emitting elements LD and the first electrode AE may be electrically connected to each other by performing a bonding process using the TC bonding method. When heat and pressure are applied to achieve bonding of the bonding electrode BDE and the first electrode AE, an intermetallic compound may be generated and grown between the bonding electrode BDE and the first electrode AE. The light-emitting elements LD and the first electrode AE may be electrically and physically connected to each other by using the intermetallic compound. However, the method of boding the light-emitting elements LD and the first electrode AE to each other is not limited to the above-described embodiments.

An intermediate electrode CTL may be provided and/or formed on the first bank BNK1 and the light-emitting elements LD. The intermediate layer CTL may be entirely coated on the first bank BNK1 through spin coating. In one or more embodiments, the intermediate layer CTL may be provided on the first bank BNK1 in a form filling the opening OP. The intermediate layer CTL may be provided between adjacent light-emitting elements LD in the opening OP of the first bank BNK1.

The intermediate layer CTL may include an organic material for reinforcing an adhesion force (or bonding force) between the light-emitting elements LD and the second electrode CE while stably fixing the light-emitting elements LD. The organic material may include, for example, at least one of a photocurable resin including a photopolymerization initiator cross-linked or cured by light, such as UV or a thermosetting resin including a thermal polymerization initiator that allows a curing reaction to be initiated by heat. For example, the thermosetting resin may include epoxy resin, amino resin, phenolic resin, polyester resin, and the like, which are configured with an organic material.

After the light-emitting elements LD and the first electrode AE are bonded to each other, the intermediate layer CTL may be entirely coated on the light-emitting elements LD and the first bank BNK1, and may be cured by light or heat. After the intermediate layer CTL is cured, a portion of the intermediate layer CTL may be removed to have a height corresponding to the length L of each of the light-emitting elements LD in at least the opening OP of the first bank BNK1 through an ashing process. In one or more embodiments, the intermediate layer CTL may have a surface SF located at the same line as the second end portion EP2 of each of the light-emitting elements LD with respect to the third direction DR3.

In one or more embodiments, the intermediate layer CTL may be an organic insulating layer including an organic material. Accordingly, the intermediate layer CTL may have a thickness of a corresponding level or more, and may have a flat surface SF (or top surface). The step coverage of components (or upper members) to be located on the top of the intermediate layer CTL can be improved. The second electrode CE may be provided and/or formed on the intermediate layer CTL.

The second electrode CE may be provided and/or formed on the second end portion EP2 of each of the light-emitting elements LD and the intermediate layer CTL. The second electrode CE may be in direct contact with the second end portion EP2 of each of the light-emitting elements LD, thereby being electrically connected to the second end portion EP2 of each of the light-emitting elements LD. For example, the second electrode CE may be in direct contact with the third layer 15 located at the second end portion EP2 of each of the light-emitting elements LD, thereby being electrically connected to the second end portion EP2 of each of the light-emitting elements LD.

The second electrode CE may be configured with various transparent conductive materials to allow light that is emitted from the light-emitting elements LD to advance in the image display direction of the display device DD with little or no loss. For example, the second electrode CE may include at least one of various transparent conductive materials (or substances) including indium tin oxide (ITO), indium zinc oxide (IZO), zinc oxide (ZnO), indium gallium zinc oxide (IGZO), indium tin zinc oxide (ITZO), or the like, and may be substantially transparent or translucent to satisfy a transmittance (e.g., predetermined transmittance, or transmittancy). However, the material of the second electrode CE is not limited to the above-described embodiments.

The above-described second electrode CE may be electrically connected to the second power line PL2 described with reference to FIG. 4. Accordingly, the voltage of the second driving power source VSS, which is applied to the second power line PL2, may be transferred to the second electrode CE.

The first electrode AE and the second electrode CE may face each other in the third direction DR3. The light-emitting elements LD may be located between the first electrode AE and the second electrode CE. In one or more embodiments, the second electrode CE may face the first electrode AE with the light-emitting elements LD interposed therebetween.

In accordance with the above-described embodiments, the second electrode CE is formed on the intermediate layer CTL having the flat surface SF to reduce or prevent a cutting failure (e.g., disconnection) that may occur due to a step difference caused by components located thereunder. Accordingly, the step coverage of the second electrode CE is improved, so that the reliability of the second electrode CE can be improved.

In accordance with the above-described embodiments, as the third layer 15 that is located at the second end portion EP2 of each of the light-emitting elements LD, the second end portion EP2 being located at the same line (or same plane) as the surface SF of the intermediate layer CTL, is configured as a semiconductor layer having conductivity, a contact resistance between the second end portion EP2 (or the third layer 15) of each of the light-emitting elements LD and the second electrode CE is reduced, so that a contact failure between each of the light-emitting elements LD and the second electrode CE can be reduced.

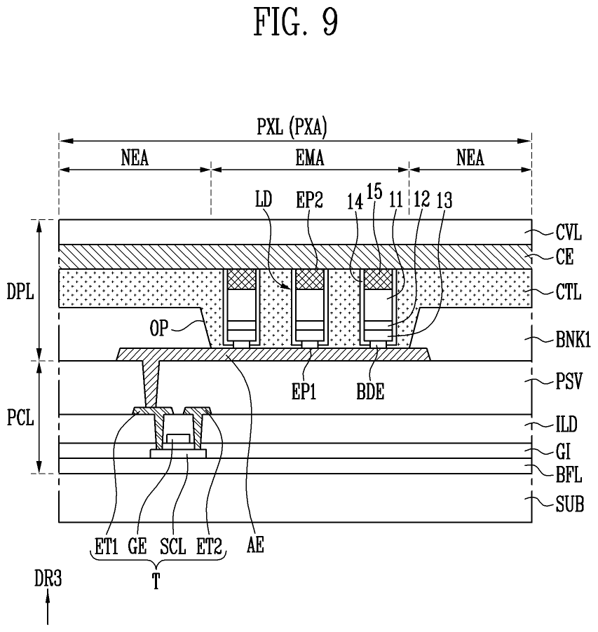

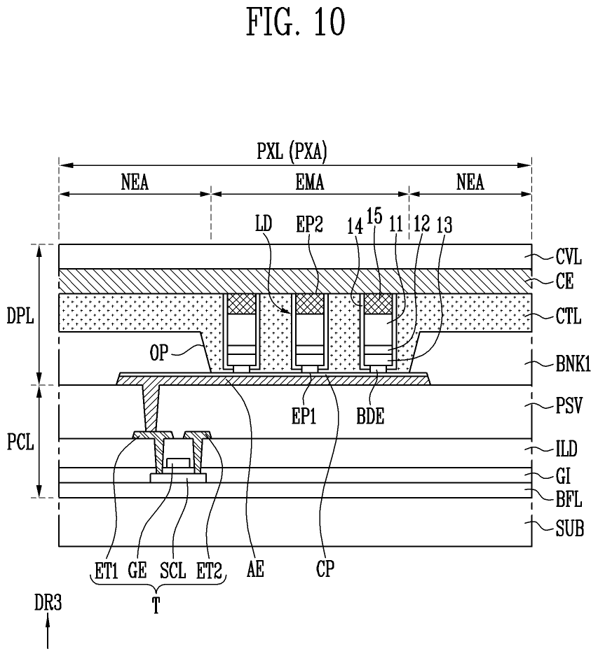

FIGS. 9 and 10 are schematic cross-sectional views illustrating a pixel including the light-emitting element LD shown in FIG. 7.

One or more embodiments shown in FIG. 10 illustrate a modified example of one or more embodiments corresponding to FIG. 9 in relation to components located on a first electrode AE.

In relation to the embodiments shown in FIGS. 9 and 10, portions that are different from those of the above-described embodiments will be described to avoid redundancy.

Referring to FIGS. 1 to 5, 7, 9, and 10, a pixel PXL in accordance with one or more embodiments may include a substrate SUB, a pixel circuit layer PCL, and a display element layer DPL.

The pixel circuit layer PCL may include the components of the pixel circuit layer PCL described with reference to FIG. 6.

The display element layer DPL may include the components of the display element layer DPL described with reference to FIG. 6. For example, the display element layer DPL may include a first electrode AE, light-emitting elements LD, a first bank BNK1, an intermediate layer CTL, a second electrode CE, and a cover layer CVL.

The first electrode AE may be located on the pixel circuit layer PCL (or the passivation layer PSV), and may be electrically connected to the transistor T of the pixel circuit layer PCL through a contact hole penetrating the passivation layer PSV. For example, the first electrode AE may be formed as a multi-layer in which indium tin oxide (ITO)/silver (Ag)/indium tin oxide (ITO) are sequentially stacked.

Light-emitting elements LD may be transferred on the first electrode AE exposed through an opening OP of the first bank BNK at least the emission area EMA, and the first electrode AE and the light-emitting elements LD may be electrically connected to each other by performing a bonding process.

Each of the light-emitting elements LD may include a first end portion EP1 and a second end portion EP2, which face each other in the third direction DR3. The first end portion EP1 may be located at a lower end portion with respect to an extending direction (or length direction) of each light-emitting element LD, and the second end portion EP2 may be located at an upper end portion of the corresponding light-emitting element LD. For example, the first end portion EP1 may be located adjacent to the first electrode AE located on the bottom of the light-emitting elements LD, and the second end portion EP2 may be located adjacent to the second electrode CE located on the top of the light-emitting elements LD.

In one or more embodiments, each of the light-emitting elements LD may include a vertical light-emitting stack structure including a bonding electrode BDE, a second layer 13, an active layer 12, a first layer 11, and a third layer 15 along the third direction DR3, and may include an insulating film 14 surrounding an outer circumferential surface of the vertical light-emitting stack structure. The bonding electrode BDE may be located at the first end portion EP1 of each of the light-emitting elements LD, and the third layer 15 may be located at the second end portion EP2 of each of the light-emitting elements LD.

The bonding electrode BDE may be in contact with the first electrode AE, thereby being electrically connected to the first electrode AE through a bonding process.

In some embodiments, a conductive pattern CP may be located on the first electrode AE as shown in FIG. 10. The conductive pattern CP may be used as a reflective member for guiding light emitted from the light-emitting elements LD in the image display direction of the display device DD. To this end, the conductive pattern may include an opaque metal having reflexibility. In some embodiments, the conductive pattern CP may include the same material as the first electrode AE described with reference to FIGS. 6 to 8, or may include at least one material selected from the materials disclosed as the material constituting the first electrode AE. When the conductive pattern CP is located on the first electrode AE, the conductive pattern CP may be used as a bonding metal bonded to the light-emitting elements LD. The bonding electrode BDE located at the first end portion EP1 of each of the light-emitting element LD may be in contact with the conductive pattern CP, thereby being electrically connected to the conductive pattern CP through a bonding process. The conductive pattern CP may be used as a connection means for electrically connecting the first electrode AE and the light-emitting elements LD to each other while being located between the first electrode AE and the light-emitting elements LD.

The intermediate layer CTL may be located on the first electrode AE and the light-emitting elements LD that are electrically connected to each other through the bonding process. The intermediate layer CTL may be located at the same line as the second end portion EP2 of each of the light-emitting elements LD, and may have a flat surface. In one or more embodiments, the intermediate layer CTL may include a curable organic material.

The second electrode CE may be located on the intermediate layer CTL. The second electrode CE may have improved step coverage as the intermediate layer CTL located on the bottom thereof has the flat surface.

The cover layer CVL may be located on the second electrode CE. The cover layer CVL may be an encapsulation substrate, or may be an encapsulation layer configured as a multi-layer. The cover layer CVL may reduce or prevent external oxygen and external moisture introduced into the display element layer DPL and the pixel circuit layer PCL. In some embodiments, the cover layer CVL may be a planarization layer for reducing a step difference generated by components located thereunder.

In some embodiments, an optical layer (see “LCL” shown in FIG. 3) may be selectively located on the top of the display element DPL. The optical layer LCL will be described in detail with reference to FIGS. 11 to 13.

FIGS. 11 to 13 are schematic cross-sectional views illustrating a pixel in accordance with one or more embodiments of the present disclosure.

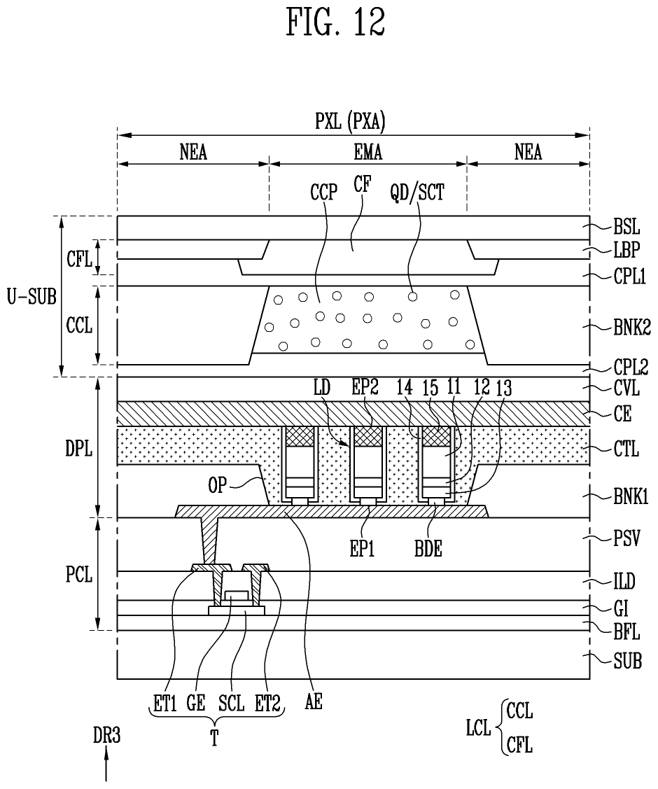

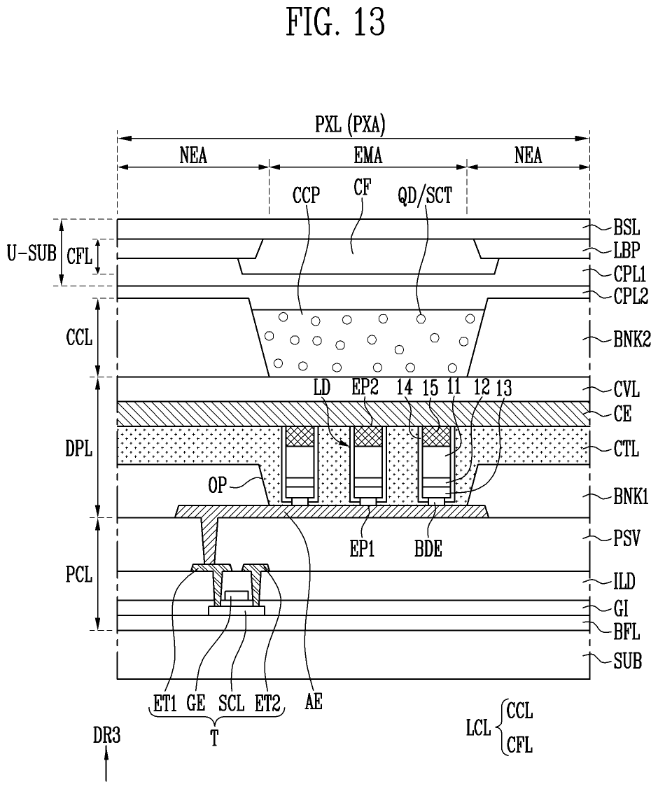

Embodiments shown in FIGS. 11 to 13 illustrate different modified examples in relation to a position of a color conversion layer CCL. For example, one or more embodiments in which a color conversion layer CCL and a color filter layer CFL are formed on a cover layer CVL through a continuous process is disclosed in FIG. 11. One or more embodiments in which an upper substrate U-SUB including a color conversion layer CCL and a color filter layer CFL is located on a cover layer CVL through an adhesion process is disclosed in FIG. 12. One or more embodiments in which a color conversion layer CCL is formed on a cover layer CVL through a continuous process, and an upper substrate U-SUB including a color filter layer CFL is located on the color conversion layer CCL through an adhesion process, is disclosed in FIG. 13.

In relation to the embodiments shown in FIGS. 11 to 13, portions that are different from those of the above-described embodiments will be mainly described to avoid redundancy.

Referring to FIGS. 1 to 5, 9, and 11, the pixel PXL may include a substrate SUB, a pixel circuit layer PCL, a display element layer DPL, a color conversion layer CCL, a color filter layer CFL, and an encapsulation layer ENC. The color conversion layer CCL and the color filter layer CFL may constitute an optical layer LCL of the pixel PXL.

The color conversion layer CCL may be provided on, and/or formed on, the display element layer DPL (or a cover layer CVL). The color conversion layer CCL may include a second bank BNK2 located in a non-emission area NEA, and a color conversion pattern CCP located in an emission area EMA.

The second bank BNK2 may be located on one surface of the cover layer CVL to correspond to a first bank BNK1. The second bank BNK2 may be a dam structure that is located in the non-emission area NEA, and may define a position at which the color conversion pattern CCP is to be supplied, thereby defining an emission area EMA of each pixel PXL.

The second bank BNK2 may include a light-blocking material. For example, the second bank BNK2 may be a black matrix, but the present disclosure is not limited thereto. In some embodiments, the second bank BNK2 may include at least one light-blocking material and/or at least one reflective material to allow light emitted from the color conversion pattern CCP to further advance in the image display direction of the display device DD, thereby improving the light emission efficiency of the color conversion pattern CCP.

The color conversion pattern CCP may include color conversion particles QD. For example, the color conversion pattern CCP may include color conversion particles QD for converting light of a first color, which is emitted from light-emitting elements LD, into light of a second color (e.g., light of a corresponding color, or light having suitable color reproducibility).

In case that the pixel PXL is a red pixel (or red sub-pixel), the color conversion pattern CCP of the pixel PXL may include color conversion particles QD of a red quantum dot that convert light of the first color, which is emitted from the light-emitting elements LD, into light of a second color (e.g., light of red).

In case that the pixel PXL is a green pixel (or green sub-pixel), the color conversion pattern CCP of the pixel PXL may include color conversion particles QD of a green quantum dot that convert light of the first color, which is emitted from the light-emitting elements LD, into light of a second color (e.g., light of green).

In case that the pixel PXL is a blue pixel (or blue sub-pixel), the color conversion pattern CCP of the pixel PXL may include color conversion particles QD of a blue quantum dot that convert light of the first color, which is emitted from the light-emitting elements LD, into light of a second color (e.g., light of blue). In some embodiments, in a case that the pixel is the blue pixel, the pixel PXL may include a light-scattering layer including light-scattering particles SCT, as opposed to the color conversion pattern CCP including the color conversion particles QD. For example, in case that the light-emitting elements LD emits blue-based light, the pixel PXL may include the light-scattering layer including the light-scattering particles SCT. The above-described light-scattering layer may be omitted in some embodiments. In other embodiments, in case that the pixel PXL is the blue pixel, transparent polymer may be provided instead of the color conversion pattern CCP.

A capping layer CPL may be provided and/or formed over the color conversion layer CCL including the second bank BNK2 and the color conversion pattern CCP.

The capping layer CPL may be an inorganic layer including an inorganic material. The capping layer CPL may include at least one of silicon nitride (SiNₓ), silicon oxide (SiOₓ), and/or silicon oxynitride (SiOₓN_{y}), or may include at least one of metal oxides an, such as aluminum oxide (AlOₓ). The capping layer CPL entirely covers the color conversion layer CCL, thereby blocking external moisture, oxygen or the like from being introduced into the color conversion layer CCL.

In some embodiments, the capping layer CPL may reduce a step difference occurring due to components located thereunder, and may have a flat surface. For example, the capping layer CPL may be an organic layer including an organic material, but the present disclosure is not limited thereto. The capping layer CPL may be a common layer commonly provided in the display area DA.

The color filter layer CFL may be provided and/or formed on the capping layer CPL. The color filter layer CFL may include a color filter CF located in the emission area EMA of the pixel PXL, and a light-blocking pattern LBP located in the non-emission area NEA of the pixel PXL.

The color filter CF may be located on one surface of the capping layer CPL to correspond to the color conversion pattern CCP. The color filter CF may include a color filter material for allowing light of the second color, which is converted in the color conversion pattern CCP, to be selectively transmitted therethrough. In case that the pixel PXL is a red pixel, the color filter CF may be a red color filter. In case that the pixel PXL is a green pixel, the color filter CF may be a green color filter. In case that the pixel PXL is a blue pixel, the color filter CF may be a blue color filter.

The light-blocking pattern LBP may be located on the one surface of the capping layer CPL to correspond to the second bank BNK2. The light-blocking pattern LBP may include a light-blocking material for reducing or preventing the likelihood of a light leakage defect in which light is leaked between adjacent color filters CF. For example, the light-blocking pattern LBP may include a black matrix, but the present disclosure is not limited thereto. Also, the light-blocking pattern LBP may reduce or prevent color mixture of lights respectively emitted from adjacent color filters CF.

The encapsulation layer ENC may be provided and/or formed on the color filter layer CFL including the color filter CF and the light-blocking pattern LBP.

The encapsulation layer ENC may include an insulating layer INS. The insulating layer INS may be an inorganic insulating layer including an inorganic material or an organic insulating layer including an organic material. The insulating layer INS may entirely cover components located thereunder, thereby blocking external moisture, external humidity, or the like from being introduced into the color filter layer CFL or into components located thereunder. In some embodiments, the insulating layer INS may be used as a planarization layer for reducing a step difference generated by components located thereunder.

The insulating layer INS may be formed as a multi-layer. For example, the insulating layer INS may include at least two inorganic insulating layers, and at least one organic insulating layer interposed between the at least two inorganic insulating layers. However, the material and/or structure of the insulating layer INS may be variously changed. In some embodiments, at least one overcoat layer, at least one filler layer, and/or another substrate may be further located on the top of the insulating layer INS.

In the pixel PXL in accordance with the above-described embodiments, the optical layer LCL including the color conversion layer CCL and the color filter layer CFL is located on the display element layer DPL through a continuous process, thereby releasing light having suitable color reproducibility through the optical layer LCL. Thus, the light emission efficiency of the pixel PXL can be improved.

In some embodiments, as shown in FIG. 12, the optical layer LCL may be formed on one surface of a base layer BSL through a continuous process, to constitute an upper substrate U-SUB as a substrate separate from the substrate SUB on which the display element layer DPL is formed. The upper substrate U-SUB may be coupled to the display element layer DPL through a cover layer CVL. To this end, the cover layer CVL may include an insulating material having insulative and adhesive properties for reinforcing adhesion between the display element layer DPL and the upper substrate U-SUB.

The upper substrate U-SUB may include the base layer BSL, a color filter layer CFL, and a color conversion layer CCL. The base layer BSL, the color filter layer CFL, and the color conversion layer CCL may be sequentially formed along the opposite direction of the third direction DR3.

The base layer BSL may be a rigid substrate or a flexible substrate, and the material or property of the base layer BSL is not particularly limited thereto. The base layer BSL may be configured with the same material as the substrate SUB, or may be configured with a material different from the material of the substrate SUB.

The color filter layer CFL may be located on the one surface of the base layer BSL to face the display element layer DPL. A color filter CF of the color filter layer CFL may be provided on the one surface of the base layer BSL to correspond to the light-emitting elements LD of the display element layer DPL in the emission area EMA. A light-blocking pattern LBP of the color filter layer CFL may be provided on the one surface of the base layer BSL to correspond to the first bank BNK1 of the display element layer DPL.

The upper substrate U-SUB may further include a first capping layer CPL1 that is located between the color filter layer CFL and a color conversion layer CCL, and that covers the color filter layer CFL to protect the color filter layer CFL.

The first capping layer CPL1 may be an inorganic insulating layer including an inorganic material or an organic insulating layer including an organic material.

The color conversion layer CCL may be located on one surface of the first capping layer CPL1 to face the display element layer DPL. A color conversion pattern CCP of the color conversion layer CCL may be located on the one surface of the first capping layer CPL1 to correspond to the light-emitting elements LD in the emission area EMA. A second bank BNK2 of the color conversion layer CCL may be located on the one surface of the first capping layer CPL1 to correspond to the first bank BNK1 in the non-emission area NEA.

The upper substrate U-SUB may further include a second capping layer CPL2 that is located between the color conversion layer CCL and the display element layer DPL, and that covers the color conversion layer CCL to protect the color conversion layer CCL.

The second capping layer CPL2 may include at least one of silicon nitride (SiNₓ), silicon oxide (SiOₓ), and/or silicon oxynitride (SiOₓN_{y}), or may include at least one of metal oxides, such as aluminum oxide (AlOₓ). However, the present disclosure is not limited thereto.

The above-described upper substrate U-SUB may be coupled to the display element layer DPL by using the cover layer CVL.

In accordance with one or more other embodiments, as shown in FIG. 13, a color conversion layer CCL may be formed on one surface of the display element layer DPL through a continuous process, and an upper substrate U-SUB including a base layer BSL and a color filter layer CFL may be located on the color conversion layer CCL through an adhesion process. A second bank BNK2 may be formed on one surface of the cover layer CVL to correspond to the first bank BNK1, and a color conversion pattern CCP may be formed on the one surface of the cover layer CVL to correspond to the light-emitting elements LD. A second capping layer CPL may be located on the color conversion layer CCL including the second bank BNK2 and the color conversion pattern CCP. The second capping layer CPL2 may include a material having an adhesive property to reinforce adhesion between the color conversion layer CCL and the upper substrate U-SUB. The upper substrate U-SUB may be provided and/or formed on the above-described second capping layer CPL2. The upper substrate U-SUB may include the base layer BSL, the color filter layer CFL, and a first capping layer CPL1, which are sequentially formed in the opposite direction of the third direction DR3. The first capping layer CPL1 may be located on the second capping layer CPL2.

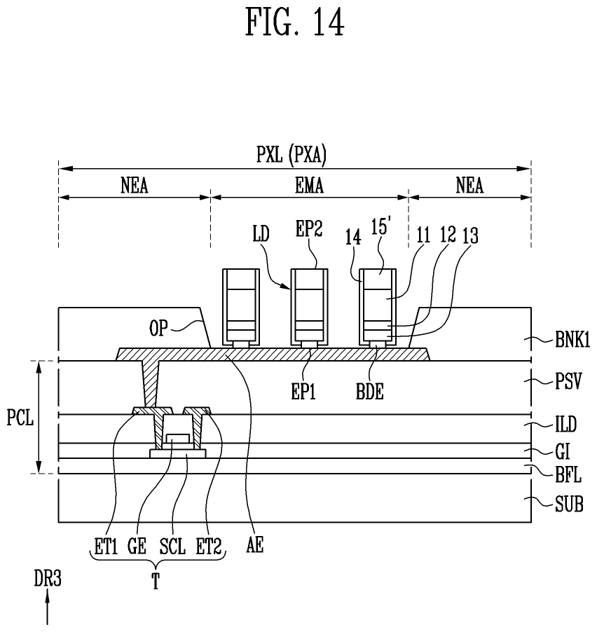

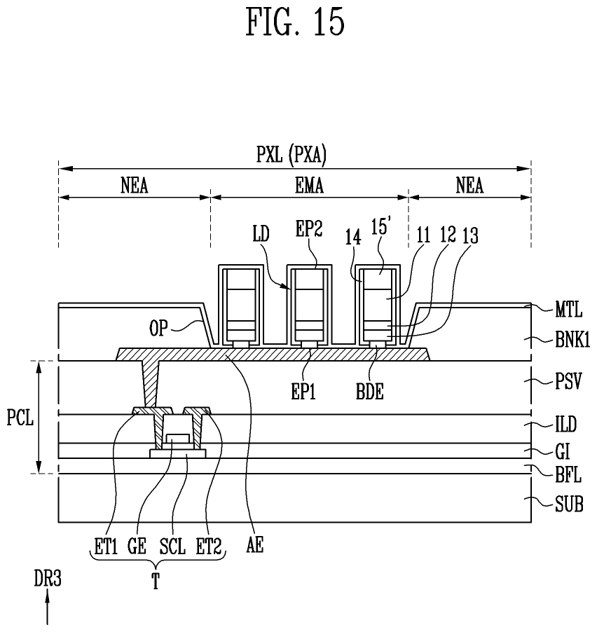

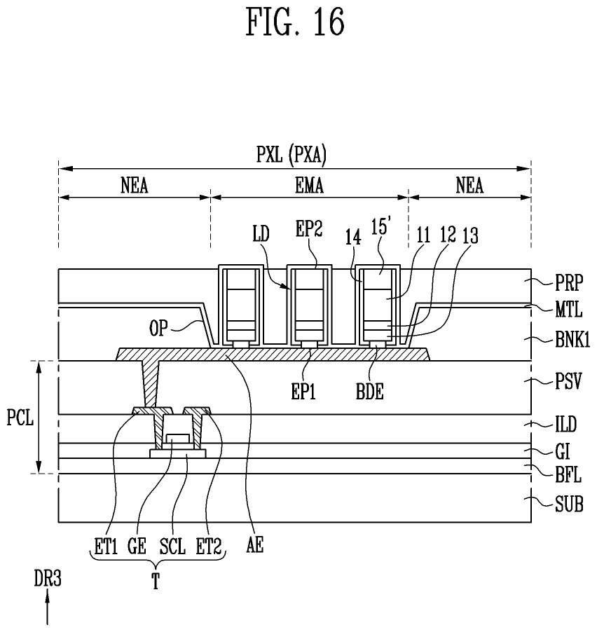

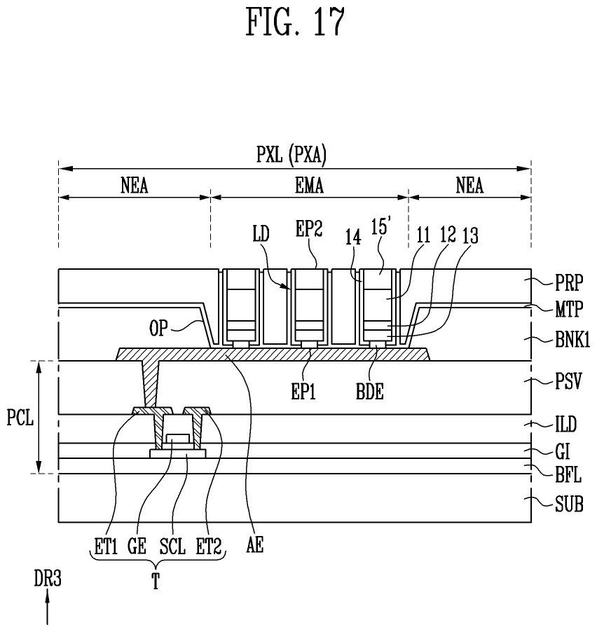

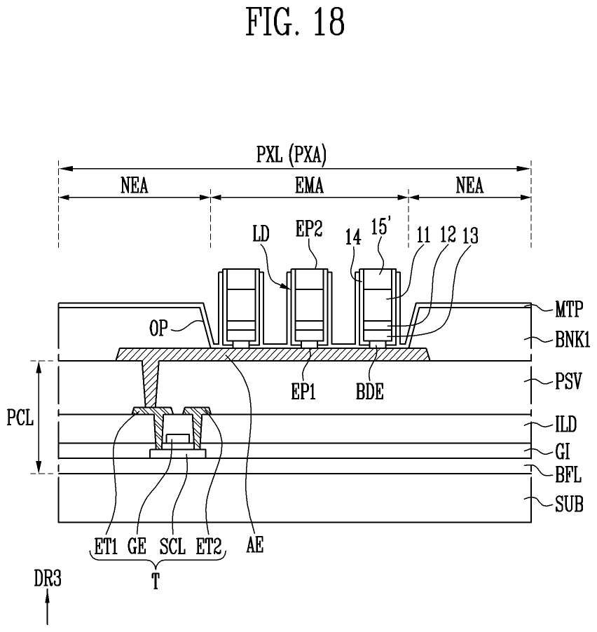

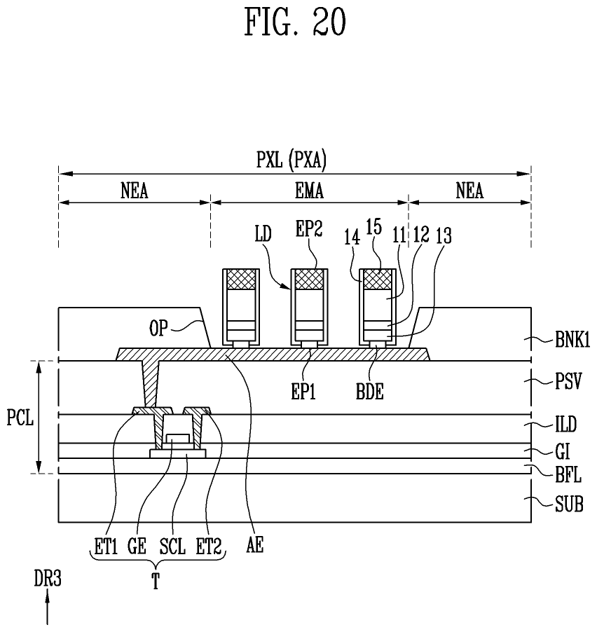

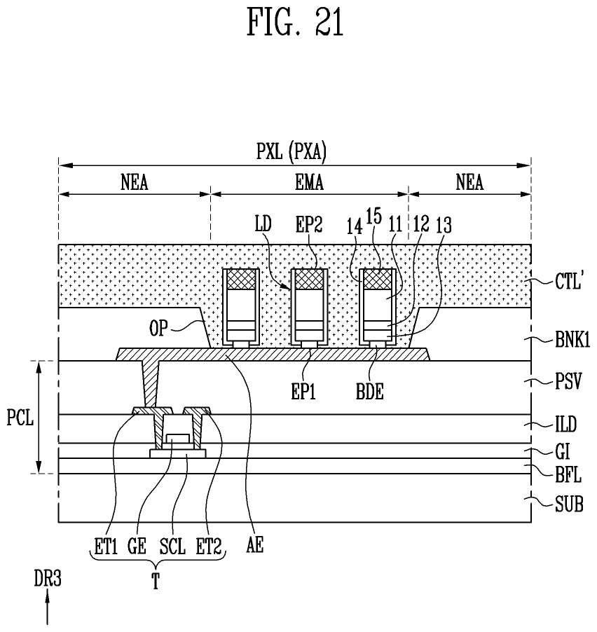

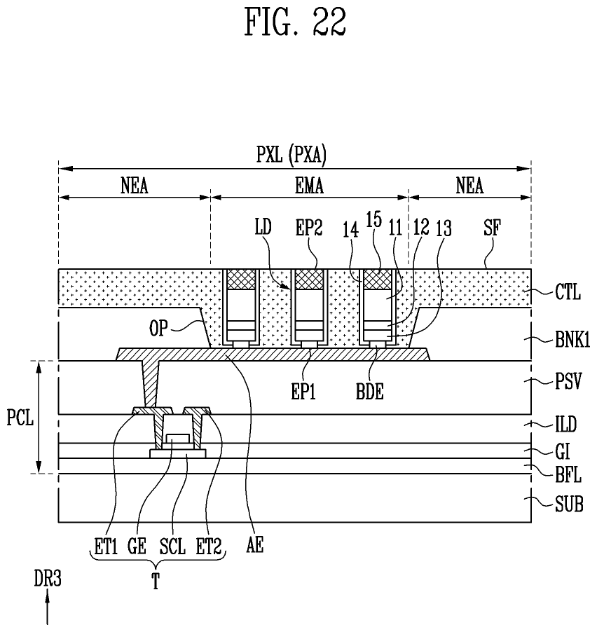

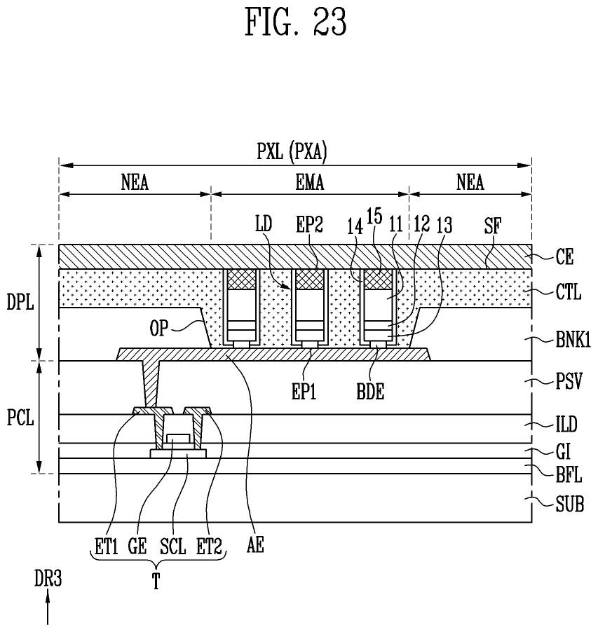

FIGS. 14 to 23 are schematic cross-sectional views sequentially illustrating a manufacturing method of a pixel PXL in accordance with one or more embodiments of the present disclosure.

Hereinafter, the manufacturing method of the pixel PXL in accordance with the embodiments of the present disclosure will be sequentially described with reference to FIGS. 14 to 23.

In one or more embodiments, although it is described that manufacturing steps of the pixel PXL are sequentially performed according to the cross-sectional views, without changing the scope of the present disclosure, some steps illustrated as being successively performed may be concurrently or substantially simultaneously performed, the sequence of the steps may be changed, one or more steps may be omitted, or one or more other steps may be further included between or amongst the steps.

In FIGS. 14 to 23, portions that are different from those of the above-described embodiments will be mainly described to avoid redundancy.

Referring to FIGS. 1 to 5, 9, and 14, a pixel circuit layer PCL is formed on a substrate SUB of a pixel area PXA.

A first electrode AE is formed on the pixel circuit layer PCL, and a first bank BNK1 including/defining an opening OP exposing one area of the first electrode AE is formed on the first electrode AE.

Light-emitting elements LD, which are separated from a growth substrate (see “101” shown in FIG. 5) to be transferred to a transfer base, are located at positions (e.g., predetermined positions) in the pixel PXL. For example, the transfer base, to which the light-emitting elements LD are transferred, is located in the pixel PXL such that a bonding electrode BDE of each of the light-emitting elements LD faces the first electrode AE. Each of the light-emitting elements LD may include a vertical light-emitting stack structure in which a bonding electrode BDE, a second layer 13, an active layer 12, a first layer 11, and a buffer semiconductor layer 15′ are sequentially located in the third direction DR3, and an insulating film 14 surrounding an outer circumferential surface of the vertical light-emitting stack structure. The buffer semiconductor layer 15′ may be an intrinsic semiconductor layer that is formed on the growth substrate 101 and is undoped with an impurity.

The light-emitting elements LD transferred to the transfer base may be located in the opening OP of the first bank BNK1. A bonding electrode BDE of each of the light-emitting elements LD may be in contact with the first electrode AE, and a buffer semiconductor layer 15′ of the corresponding light-emitting element LD may be in contact with the transfer base. The bonding electrode BDE may be located at a first end portion EP1 of each light-emitting element LD, and the buffer semiconductor layer 15′ may be located at a second end portion EP2 of each light-emitting element LD.

The transfer base may be a light transmissive substrate including sapphire, glass, polyimide, and the like. Accordingly, the transfer base can allow a laser beam irradiated from the top and/or the bottom to be transmitted therethrough. A sacrificial layer may be provided between the transfer base and the light-emitting elements LD. The sacrificial layer may selectively include materials that are suitably separated by laser irradiated laser among materials having adhesion (or viscosity). When laser is irradiated onto the transfer base after the bonding electrodes BDE of the light-emitting elements LD and the first electrode AE are bonded to each other, the sacrificial layer and the light-emitting elements LD may be physically separated from each other. For example, the sacrificial layer may lose an adhesion function when laser is irradiated. Accordingly, the buffer semiconductor layer 15′ may be exposed to the outside. In some embodiments, the buffer semiconductor layer 15′ may be used as the sacrificial layer.

Referring to FIGS. 1 to 5, 9, 14, and 15, a metal layer MTL is entirely formed over the first bank BNK1, the light-emitting elements LD, and the first electrode AE.

The metal layer MTL may include at least one of indium zinc oxide, aluminum, and/or indium gallium zinc oxide, but the present disclosure is not limited thereto. The kind of material (or substance) of the metal layer MTL may be variously selected within a range in which components. For example, the first bank BNK1 and the first electrode AE, which are located on the bottom of the metal layer MTL, can be completely covered and protected by an impurity doped in a process to be described with reference to FIG. 19.

In one or more embodiments, the metal layer MTL located over the light-emitting elements LD may surround the insulating film 14 and the buffer semiconductor layer 15′ of each of the light-emitting elements LD.

Referring to FIGS. 1 to 5, 9, and 14 to 16, after a photosensitive material is entirely coated on the metal layer MTL, a portion of the photosensitive material is removed through a photolithography process using a mask, thereby forming a photosensitive pattern PRP that exposes, to the outside, the metal layer located on the second end portions EP2 of the light-emitting elements LD.

Referring to FIGS. 1 to 5, 9, and 14 to 17, the metal layer MTL exposed to the outside is removed through a primary etching process using the photosensitive pattern PRP as an etching mask, thereby forming a metal pattern MTP that exposes, to the outside, the buffer semiconductor layer 15′ located at the second end portion EP2 of each of the light-emitting elements LD.

The above-described primary etching process may be a wet etching process.

Referring to FIGS. 1 to 5, 9, and 14 to 18, the photosensitive pattern PRP is removed through a stripping process, and the metal pattern MTP and the buffer semiconductor layer 15′ (or the second end portion EP2) of each of the light-emitting elements LD are exposed.

Referring to FIGS. 1 to 5, 9, and 14 to 19, an impurity is doped on the metal pattern MTP and the buffer semiconductor layer 15′ of each light-emitting element LD, which are exposed to the outside. A low-concentration n-type impurity or a high-concentration n-type impurity may be used as the impurity, but the present disclosure is not limited thereto.

As the impurity is doped, the buffer semiconductor layer 15′ of each light-emitting element LD, which is an intrinsic semiconductor layer, reacts with the impurity, thereby forming a third layer 15 having conductivity. For example, through the above-described process, the buffer semiconductor layer 15′ of each light-emitting element LD may be formed as the third layer 15 as a semiconductor layer having conductivity.

The metal pattern MTP might not be influenced by the impurity. Accordingly, the metal pattern MTP may be used as a barrier layer covering the first bank BNK1, the first electrode AE, and the insulating film 14 of each light-emitting element LD, which are located on the bottom thereof in a process of doping the impurity.

Referring to FIGS. 1 to 5, 9, and 14 to 20, the metal pattern MTP is removed through a secondary etching process, thereby exposing the first bank BNK1, the light-emitting elements LD, and the first electrode AE located in the opening of the first bank BNK1.

The above-described secondary etching process may be a wet etching process.

Referring to FIGS. 1 to 5, 9, and 14 to 21, an intermediate base layer CTL′ is entirely formed over the first bank BNK1, the light-emitting elements LD, and the first electrode AE. The intermediate base layer CTL′ may be a base material of an intermediate layer CTL, and may have a thickness that is greater than a length (see “L” shown in FIG. 7) of each light-emitting element LD to sufficiently cover the first bank BNK1, the light-emitting elements LD, and the first electrode AE.

The intermediate base layer CTL′ may be provided in a form filling the opening OP of the first bank BNK1, and may be formed even between the light-emitting elements LD located in the opening OP. The intermediate base layer CTL′ may be cured by heat or light, to stably fix the light-emitting elements LD.

Referring to FIGS. 1 to 5, 9, and 14 to 22, a portion of the intermediate base layer CTL′ is removed through an ashing process, thereby forming the intermediate layer CTL that exposes, to the outside, the third layer 15 located at the second end portion EP2 of each of the light-emitting elements LD.

Through the above-described process, the intermediate layer CTL may be located at the same line as the second end portion EP2 of each light-emitting element LD in a vertical direction, or with respect to the third direction DR3, and may have a flat surface SF. In one or more embodiments, the surface SF of the intermediate layer CTL may be located at the same level as the second end portion EP2 of each light-emitting element LD (or an upper surface of the third layer 15).

Referring to FIGS. 1 to 5, 9, and 14 to 23, a second electrode CE is formed on the intermediate layer CTL. The second electrode CE may be in contact with a third layer 15 located at a second end portion EP2 of each light-emitting element LD, thereby being electrically connected to the third layer 15 of the corresponding light-emitting element LD.

Meanwhile, when light-emitting elements are transferred on an anode to be bonded to each other, and then an intrinsic semiconductor layer located at a second end portion of each of the light-emitting elements is removed through a dry etching process in the existing manufacturing method, an organic layer (e.g., the intermediate layer CTL of the embodiment) located on the light-emitting layer is removed together with the intrinsic semiconductor layer in the process of removing the intrinsic semiconductor layer, and therefore, a thickness of the organic layer may become less than a length of the light-emitting elements. As the step coverage of a cathode located on the organic layer is deteriorated, a cutting phenomenon of the cathode or the like occurs due to a step difference of components located under the cathode, and therefore, the reliability of the cathode may be deteriorated.

Accordingly, in the pixel PXL (or the display device DD) formed through the above-described manufacturing method, after light-emitting elements LD are transferred on a first electrode AE to be bonded to each other, a buffer semiconductor layer 15′ of each of the light-emitting elements LD is not removed, but an impurity is doped into the buffer semiconductor layer 15′ through an impurity doping process using the metal layer MTL (or the metal pattern MTP) as a barrier layer, thereby forming the third layer 15 having conductivity. Subsequently, there is formed an intermediate layer CTL that is located at the same line as second end portions EP2 of the light-emitting elements LD, each of which including the third layer 15, and that has a flat surface SF, and a second electrode CE is formed on the intermediate layer CTL. Thus, the step coverage of the second electrode CE is improved, and accordingly, the reliability of the second electrode CE can be improved.

Also, in the pixel PXL (or the display device DD) formed through the above-described manufacturing method, the third layer 15 of each light-emitting element LD, which has conductivity, and the second electrode CE are connected to each other while being in direct contact with each other, so that the contact resistance between the light-emitting elements LD and the second electrode CE can be reduced. Accordingly, a contact failure between the light-emitting elements LD and the second electrode CE can be reduced, thereby improving the reliability of the pixel PXL.

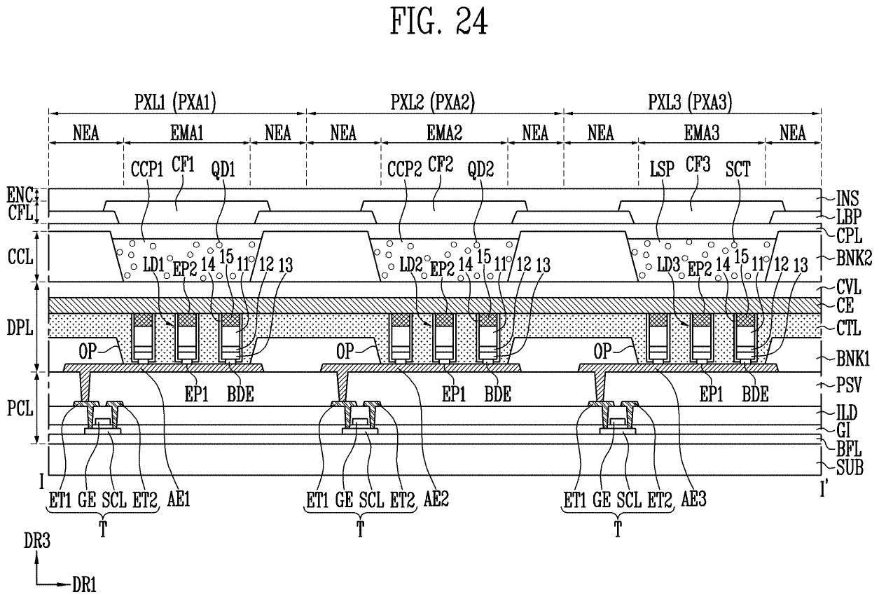

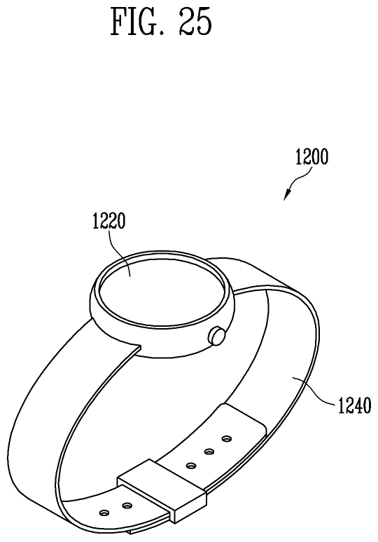

FIG. 24 is a schematic cross-sectional view taken along line I-I′ shown in FIG. 1.

In relation to one or more embodiments corresponding to FIG. 24, portions that are different from those of the above-described embodiments will be mainly described to avoid redundancy. Portions not particularly described in the one or more embodiments corresponding to FIG. 24 follow those of the above-described embodiments. In addition, identical reference numerals refer to identical components, and similar reference numerals refer to similar components.

Referring to FIGS. 1 and 24, a first pixel PXL1 (or first sub-pixel), a second pixel PXL2 (or second sub-pixel), and a third pixel PXL3 (or third sub-pixel) may be arranged in a first direction DR1. Each of the first, second, and third pixels PXL1, PXL2, and PXL3 may be the pixel PXL described with reference to FIGS. 9 and 11. The first pixel PXL1 may be a red pixel, the second pixel PXL2 may be a green pixel, and the third pixel PXL3 may be a blue pixel. However, the present disclosure is not limited thereto.

The first pixel PXL1 may be located in a first pixel area PXA1 provided in the display area DA of the substrate SUB. The first pixel area PXA1 may include a first emission area EMA1, and a non-emission area NEA located at at least one side of the first emission area EMA1 (or adjacent to the first emission area EMA1).

The second pixel PXL2 may be located in a second pixel area PXA2 provided in the display area DA. The second pixel area PXA2 may include a second emission area EMA2, and a non-emission area NEA located at at least one side of the second emission area EMA2 (or adjacent to the second emission area EMA2).

The third pixel PXL3 may be located in a third pixel area PXA3 provided in the display area DA. The third pixel area PXA3 may include a third emission area EMA3, and a non-emission area NEA located at at least one side of the third emission area EMA3 (or adjacent to the third emission area EMA3).

Each of the first, second, and third pixels PXL1, PXL2, and PXL3 may include the substrate SUB, a pixel circuit layer PCL, a display element layer DPL, a color conversion layer CCL, a color filter layer CFL, and an encapsulation layer ENC.

A display element layer DPL of the first pixel PXL1 may include first light-emitting elements LD1 located in at least the first emission area EMA1 between a (1-1)th electrode AE1 and a second electrode CE. Each of the first light-emitting elements LD1 may be located on the (1-1)th electrode AE1 exposed by an opening OP of a first bank BNK1. Each of the first light-emitting elements LD1 may include a vertical light-emitting stack structure in which a bonding electrode BDE, a second layer 13, an active layer 12, a first layer 11, and a third layer 15 are sequentially stacked along the third direction DR3, and an insulating film 14 surrounding an outer circumferential surface of the vertical light-emitting stack structure. The bonding electrode BDE may be located at a first end portion EP1 of each of the first light-emitting elements LD1, thereby being in contact with the (1-1)th electrode AE1, and the third layer 15 may be located at a second end portion EP2 of each of the first light-emitting elements LD1, thereby being in contact with the second electrode CE.

A display element layer DPL of the second pixel PXL2 may include second light-emitting elements LD2 located in at least the second emission area EMA2 between a (1-2)th electrode AE2 and the second electrode CE. Each of the second light-emitting elements LD2 may be located on the (1-2)th electrode AE2 exposed by an opening OP of the first bank BNK1. Each of the second light-emitting elements LD2 may include a vertical light-emitting stack structure in which a bonding electrode BDE, a second layer 13, an active layer 12, a first layer 11, and a third layer 15 are sequentially stacked along the third direction DR3, and an insulating film 14 surrounding an outer circumferential surface of the vertical light-emitting stack structure. The bonding electrode BDE may be located at a first end portion EP1 of each of the second light-emitting elements LD2, thereby being in contact with the (1-2)th electrode AE2, and the third layer 15 may be located at a second end portion EP2 of each of the second light-emitting elements LD2, thereby being in contact with the second electrode CE.

A display element layer DPL of the third pixel PXL3 may include third light-emitting elements LD3 located in at least the third emission area EMA3 between a (1-3)th electrode AE3 and the second electrode CE. Each of the third light-emitting elements LD3 may be located on the (1-3)th electrode AE3 exposed by an opening OP of the first bank BNK1. Each of the third light-emitting elements LD3 may include a vertical light-emitting stack structure in which a bonding electrode BDE, a second layer 13, an active layer 12, a first layer 11, and a third layer 15 are sequentially stacked along the third direction DR3, and an insulating film 14 surrounding an outer circumferential surface of the vertical light-emitting stack structure. The bonding electrode BDE may be located at a first end portion EP1 of each of the third light-emitting elements LD3, thereby being in contact with the (1-3)th electrode AE3, and the third layer 15 may be located at a second end portion EP2 of each of the third light-emitting elements LD3, thereby being in contact with the second electrode CE.

A color conversion layer CCL of the first pixel PXL1 may include a first color conversion pattern CCP1 located in the first emission area EMA1. The first color conversion pattern CCP1 may include first color conversion particles QD1. For example, the first color conversion particles QD1 may be red quantum dots. The first color conversion pattern CCP1 may include a plurality of first color conversion particles QD1 distributed in a matrix material (e.g., predetermined matrix material), such as base resin. The above-described first color conversion pattern CCP1 may be located on a display element layer DPL (or a cover layer CVL) to correspond to the first light-emitting elements LD1.

A color conversion layer CCL of the second pixel PXL2 may include a second color conversion pattern CCP2 located in the second emission area EMA2. The second color conversion pattern CCP2 may include second color conversion particles QD2. For example, the second color conversion particles QD2 may be green quantum dots. The second color conversion pattern CCP2 may include a plurality of second color conversion particles QD2 distributed in a matrix material (e.g., predetermined matrix material), such as base resin. The above-described second color conversion pattern CCP2 may be located on a display element layer DPL (or the cover layer CVL) to correspond to the second light-emitting elements LD2.

A color conversion layer CCL of the third pixel PXL3 may include a light-scattering layer LSP located in the third emission area EMA3. The light-scattering layer LSP may include a plurality of light-scattering particles SCT distributed in a matrix material (e.g., predetermined matrix material), such as base resin. The light-scattering layer LSP may include light-scattering particles SCT, such as silica, but the material constituting the light-scattering particles SCT is not limited thereto. In some embodiments, the light-scattering particles SCT may be omitted, and the light-scattering layer LSP configured with transparent polymer may be provided. The above-described light-scattering layer LSP may be located on a display element layer DPL (or the cover layer CVL) to correspond to the third light-emitting elements LD3.

The color conversion layer CCL of each of the first, second, and third pixels PXL1, PXL2, and PXL3 may include a second bank BNK2. The second bank BNK2 may be located in the non-emission area NEA of each of the first, second, and third pixels PXL1, PXL2, and PXL3. The second bank BNK2 may be a structure that surrounds the first, second, and third emission areas EMA1, EMA2, and EMA3, and defines a position at which each of the first color conversion pattern CCP1, the second color conversion pattern CCP2, and the light-scattering layer LSP is to be supplied, thereby finally defining the first emission area EMA1, the second emission area EMA2, and the third emission area EMA3. The second bank BNK2 may be a black matrix, but the present disclosure is not limited thereto.

A capping layer CPL may be provided and/or formed on the color conversion layer CCL of each of the first, second, and third pixels PXL1, PXL2, and PXL3.

A color filter layer CFL of the first pixel PXL1 may include a first color filter CF1 located in the first emission area EMA1. The first color filter CF1 may be a red color filter. The first color filter CF1 may be located on the capping layer CPL to correspond to the first color conversion pattern CCP1.

A color filter layer CFL of the second pixel PXL2 may include a second color filter CF2 located in the second emission area EMA2. The second color filter CF2 may be a green color filter. The second color filter CF2 may be located on the capping layer CPL to correspond to the second color conversion pattern CCP2.

A color filter layer CFL of the third pixel PXL3 may include a third color filter CF3 located in the third emission area EMA3. The third color filter CF3 may be a blue color filter. The third color filter CF3 may be located on the capping layer CPL to correspond to the light-scattering layer LSP.

The color filter layer CFL of each of the first, second, and third pixels PXL1, PXL2, and PXL3 may include a light-blocking pattern LBP. The light-blocking pattern LBP may be located between the first, second, and third color filters CF1, CF2, and CF3, thereby reducing or preventing color mixture of lights respectively transmitted through the first color filter CF1, the second color filter CF2, and the third color filter CF3. The light-blocking pattern LBP may include a black matrix, but the present disclosure is not limited thereto. In some embodiments, after the first, second, and third color filters CF1, CF2, and CF3 are located to overlap with each other in the non-emission area NEA, the first, second, and third color filters CF1, CF2, and CF3 overlapping with each other are used as a light-blocking member, thereby reducing or preventing color mixture of lights respectively transmitted through the first, second, and third emission areas EMA1, EMA2, and EMA3.

The encapsulation layer ENC including an insulating layer INS may be provided and/or formed on the color filter layer CFL of each of the first, second, and third pixels PXL1, PXL2, and PXL3.

Hereinafter, fields of application of the display device DD in accordance with embodiments of the present disclosure will be described with reference to FIGS. 25 to 28.

FIGS. 25 to 28 are schematic views illustrating application examples of the display device in accordance with embodiments of the present disclosure.

First, referring to FIGS. 1 and 25, the display device DD may be applied to a smart watch 1200 including a display part 1220 and a strap part 1240. The smart watch 1200 is a wearable electronic device, and may have a structure in which the strap part 1240 is mounted on a wrist of a user. The display device DD is applied to the display part 1220, so that image data including time information can be provided to the user.

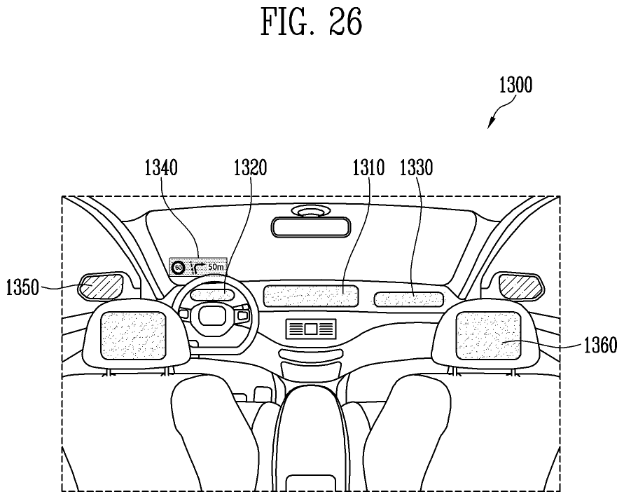

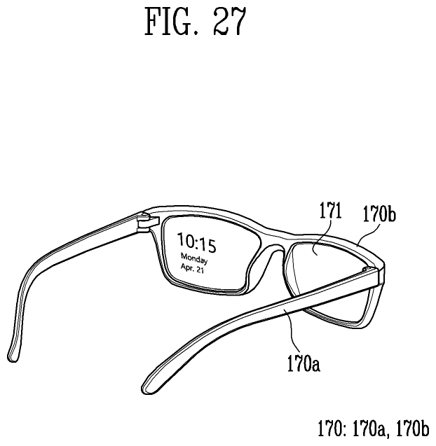

Referring to FIGS. 1 and 26, the display device DD may be applied to an automotive display 1300. The automotive display 1300 may mean an electronic device provided at the inside/outside of a vehicle to provide image data.

For example, the display device DD may be applied to at least one of an infotainment panel 1310, a cluster 1320, a co-driver display 1330, a heads-up display 1340, a side mirror display 1350, and/or a read seat display 1360, which are provided in the vehicle.

Referring to FIGS. 1 and 27, the display device DD may be applied to smart glasses including a frame 170 and a lens part 171. The smart glasses are a wearable electronic device that can be worn on the face of a user, and may have a structure in which a portion of the frame 170 is folded or unfolded. For example, the smart glasses may be a wearable device for Augmented Reality (AR).

The frame 170 may include a housing 170b, which supports the lens part 171, and a leg part 170a for allowing the user to wear the smart glasses. The leg part 170a may be connected to the housing 170b by a hinge to be folded or unfolded.

A battery, a touch pad, a microphone, a camera, and the like may be built in the frame 170. In addition, a projector for outputting light, a processor for controlling a light signal, etc., and the like may be built in the frame 170.

The lens part 171 may be an optical member that allows light to be transmitted therethrough, or that allows light to be reflected thereby. The lens part 171 may include glass, transparent synthetic resin, etc. Also, the lens part 171 may allow an image caused by a light signal transmitted from the projector of the frame 170 to be reflected by a rear surface (e.g., a surface in a direction facing eyes of the user) of the lens part 171, thereby enabling the eyes of the user to recognize the image. For example, as shown in the drawing, the user may recognize information including time, data, and the like, which are displayed on the lens part 171. That is, the lens part 171 is a kind of display device, and the display device DD may be applied to the lens part 171.

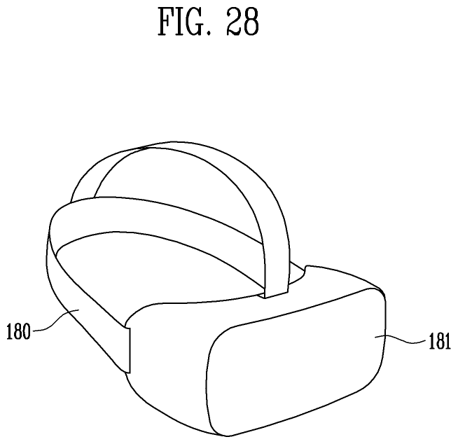

Referring to FIGS. 1 and 28, the display device DD may be applied to a Head Mounted Display (HMD) including a head mounted band 180 and a display accommodating case 181. The HMD is a wearable electronic device that can be worn on the head of a user.

The head mounted band 180 is a part connected to the display accommodating case 181, to fix the display accommodating case 181. In the drawing, it is illustrated that the head mounted band 180 can surround a top surface and both side surfaces of the head of the user. However, the present disclosure is not limited thereto. The head mounted band 180 is used to fix the HMD to the head of the user, and may be formed in the shape of a glasses frame or a helmet.

The display accommodating case 181 accommodates the display device, and may include at least one lens. The at least one lens is a part that provides an image to the user. For example, the display device DD may be applied to a left-eye lens and a right-eye lens, which are implemented in the display accommodating case 181.

In accordance with the present disclosure, an impurity is doped into a semiconductor layer located at a second end portion of a light-emitting element in contact with a second electrode (or cathode), thereby allowing the semiconductor layer to have conductivity. Thus, a contact resistance between the second end portion of the light-emitting element and the second electrode is reduced, thereby reducing a contact failure between the light-emitting element and the second electrode. Accordingly, the reliability of the display device can be improved.

In accordance with the present disclosure, step coverage of the second electrode, thereby further improving the reliability of the display device.

Example embodiments have been disclosed herein, and although specific terms are employed, they are used in, and are to be interpreted in, a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the scope of the present disclosure as set forth in the following claims, with functional equivalents thereof to be included therein.

What is claimed is:

1. A display device comprising:
a first electrode above a surface of a substrate;
light-emitting elements comprising:
a first end portion above, contacting, and electrically connected to, the first electrode;
a second end portion opposite to the first end portion with respect to a direction that is perpendicular to the surface of the substrate;
a bonding electrode;
a second layer;
an active layer;
a first layer; and
a third layer having conductivity by doping an impurity into an intrinsic semiconductor layer;
an intermediate layer over the light-emitting elements, and exposing the second end portion; and
a second electrode above the intermediate layer, and contacting and electrically connected to the second end portion.

2. The display device of claim 1, wherein the bonding electrode is at the first end portion, and electrically connected to the first electrode, and
wherein the third layer is at the second end portion, and electrically connected to the second electrode.

3. The display device of claim 2, wherein the first layer comprises an n-type semiconductor layer, and the second layer comprises a p-type semiconductor layer.

4. The display device of claim 3, wherein the intermediate layer comprises an organic layer.

5. The display device of claim 4, further comprising:
a first bank defining an opening above the first electrode to expose an area of the first electrode; and
a cover layer above the second electrode.

6. The display device of claim 5, wherein the intermediate layer is between the first bank and the light-emitting elements in the opening of the first bank in plan view, thereby fixing the light-emitting elements, and has a flat surface.

7. The display device of claim 5, further comprising:
a color conversion layer comprising a color conversion pattern above the cover layer and corresponding to the light-emitting elements, and a second bank adjacent to the color conversion pattern, above the cover layer, and corresponding to the first bank; and
a color filter layer above the color conversion layer, and configured to selectively transmit light emitted from the color conversion layer.

8. The display device of claim 1, further comprising a conductive pattern between the first electrode and the first end portion of the light-emitting elements.

9. A display device comprising:
a substrate comprising an emission area and a non-emission area;
a passivation layer above a surface of the substrate;
a (1-1)th electrode, a (1-2)th electrode, and a (1-3)th electrode above the passivation layer, and spaced apart;
a first bank above the (1-1)th electrode, the (1-2)th electrode, the (1-3)th electrode, and the passivation layer, and defining an opening exposing respective areas of the (1-1)th electrode, the (1-2)th electrode, and the (1-3)th electrode;
first light-emitting elements comprising a first end portion above, contacting, and electrically connected to the (1-1)th electrode, and a second end portion opposite to the first end portion in a direction perpendicular to the surface of the substrate;
second light-emitting elements comprising a first end portion above, contacting, and electrically connected to the (1-2)th electrode, and a second end portion opposite to the first end portion in the direction perpendicular to the surface of the substrate;
third light-emitting elements each comprising a first end portion above, contacting, and electrically connected to the (1-3)th electrode, and a second end portion opposite to the first end portion in the direction perpendicular to the surface of the substrate;
an intermediate layer over the first light-emitting elements, the second light-emitting elements, the third light-emitting elements, and the first bank, and exposing the second end portions of the first light-emitting elements, the second light-emitting elements, and the third light-emitting elements; and
a second electrode above the intermediate layer, contacting the second end portions of the first light-emitting elements, the second light-emitting elements, and the third light-emitting elements, and electrically connected to the first light-emitting elements, the second light-emitting elements, and the third light-emitting elements,
wherein the first light-emitting elements, the second light-emitting elements, and the third light-emitting elements comprise a bonding electrode, a second layer, an active layer, a first layer, and a third layer, which has conductivity by doping an impurity into an intrinsic semiconductor layer, that are sequentially arranged toward the second electrode.

10. The display device of claim 9, wherein the bonding electrode is at the first end portion, and is electrically connected to a respective one of the (1-1)th electrode, the (1-2)th electrode, and the (1-3)th electrode, and
wherein the third layer is at the second end portion, and is electrically connected to the second electrode.

11. The display device of claim 9, wherein the first layer comprises an n-type semiconductor layer, and the second layer comprises a p-type semiconductor layer.

12. A method of manufacturing a display device, the method comprising:
forming a first electrode above a surface of a substrate;
forming, above the first electrode, a first bank defining an opening exposing an area of the first electrode;
preparing light-emitting elements comprising a first end portion, and a second end portion that is opposite to the first end portion;
transferring the light-emitting elements such that the first end portion contacts the first electrode;
forming a metal layer over the light-emitting elements;
forming, above the metal layer, a photosensitive pattern exposing an area of the metal layer corresponding to the second end portion;
forming a metal pattern exposing the second end portion by removing the area of the metal layer through an etching process using the photosensitive pattern as an etching mask;
exposing the metal pattern by removing the photosensitive pattern;
doping the metal pattern and the second end portion with an impurity;
exposing the light-emitting elements and the first bank by removing the metal pattern; and
forming an intermediate layer over the light-emitting elements and the first bank.

13. The method of claim 12, wherein the forming of the intermediate layer comprises:
coating an intermediate base layer over the light-emitting elements and the first bank;
curing the intermediate base layer; and
exposing the second end portion by removing a portion of the intermediate base layer through an ashing process.

14. The method of claim 13, wherein the intermediate layer comprises an organic layer.

15. The method of claim 14, further comprising forming, above the intermediate layer, a second electrode contacting the second end portion to be electrically connected to the light-emitting elements.

16. The method of claim 15, wherein the light-emitting elements comprise a bonding electrode at the first end portion and contacting the first electrode, a second layer above the bonding electrode, an active layer above the second layer, a first layer above the active layer, and a third layer above the first layer, at the second end portion, and contacting the second electrode.

17. The method of claim 16, wherein, in the transferring of the light-emitting elements, the first layer comprises an n-type semiconductor layer, the second layer comprises a p-type semiconductor layer, and the third layer comprises an intrinsic semiconductor layer.

18. The method of claim 17, wherein, in the doping the metal pattern and the second end portion, the third layer has conductivity by doping the impurity into the intrinsic semiconductor layer.

19. The method of claim 12, wherein, in the doping the metal pattern and the second end portion, the metal pattern comprises a barrier layer covering the first bank, the first electrode, and a side of the light-emitting elements.

20. The method of claim 12, wherein the metal layer comprises at least one of indium zinc oxide, aluminum, and/or indium gallium zinc oxide.
